(19) United States
(12) Patent Application Publication
(10) Pub. No.: US 2025/0169036 A1
(43) Pub. Date: May 22, 2025

(54) REFRIGERANT CIRCULATION DEVICE, COOLING DEVICE, AND PUMP UNIT

(71) Applicant: NIDEC CORPORATION, Kyoto (JP)

(72) Inventors: Toshihiko TOKESHI, Kyoto (JP); Takehito TAMAOKA, Kyoto (JP); Shinsuke HAMANO, Kyoto (JP); Taku MURAKAMI, Kyoto (JP); Tomoaki ANDO, Kyoto (JP); Yuji HAGIWARA, Kyoto (JP)

(21) Appl. No.: 18/950,490

(22) Filed: Nov. 18, 2024

Related U.S. Application Data
(60) Provisional application No. 63/599,817, filed on Nov. 16, 2023.

(51) Int. Cl. H05K 7/20

(52) U.S. Cl. CPC H05K 7/20272; H05K 7/20254

(57) ABSTRACT

A refrigerant circulation device includes a primary flow path, a secondary flow path, a heat exchanger, a housing, a power connector, two inflow ports, and two outflow ports. The primary refrigerant flows through the primary flow path. The secondary refrigerant flows through the secondary flow path. The heat exchanger is connected to the primary and secondary flow paths. The housing includes two first outer side surfaces extending along a first direction in a plan view and two second outer side surfaces extending along a second direction intersecting the first direction, the housing accommodating the primary flow path, the secondary flow path, and the heat exchanger. The power connector is provided on and protrudes from the first outer side surface. The two inflow ports are positioned on the first outer side surface provided with the power connector and communicate with the primary flow path and the secondary flow path, respectively.

### CROSS-REFERENCE TO RELATED APPLICATIONS

The present application claims priority under 35 U.S.C. § 119 to U.S. Patent Application No. 63/599,817, filed on Nov. 16, 2023, the entire contents of which are hereby incorporated herein by reference.

### 1. FIELD OF THE INVENTION

The present disclosure relates to refrigerant circulation devices, cooling devices, and pump assemblies.

### 2. BACKGROUND

Conventionally, there has been known a refrigerant circulation device that cools a heat source such as a central processing unit (CPU) by transmitting heat received from the heat source to a refrigerant circulating inside the refrigerant circulation device.

A conventional refrigerant circulation device internally includes a flow path of a primary refrigerant and a flow path of a secondary refrigerant. An inflow port and an outflow port of the primary refrigerant and an inflow port and an outflow port of the secondary refrigerant are provided on a back surface of the refrigerant circulation device, and are connected to pipes, respectively.

In recent years, there is a demand for arranging a power unit of a refrigerant circulation device on a back surface of the refrigerant circulation device and directly connecting the power unit to a power supply unit fixed to a rack or the like. However, when the power unit is arranged on the back surface of the refrigerant circulation device, routing of pipes through which the refrigerant flows becomes complicated, and the plurality of pipes and the power unit may interfere with each other.

### SUMMARY

A refrigerant circulation device according to an example embodiment of the present disclosure includes a primary flow path, a secondary flow path, a heat exchanger, a housing, a power connector, two inflow ports, and two outflow ports. The primary refrigerant flows through the primary flow path. The secondary refrigerant flows through the secondary flow path. The heat exchanger is connected to the primary flow path and the secondary flow path. The housing includes two first outer side surfaces extending along a first direction in a plan view and two second outer side surfaces extending along a second direction intersecting the first direction, the housing accommodating the primary flow path, the secondary flow path, and the heat exchanger. The power connector is provided on the first outer side surface and protrudes from the first outer side surface. The two inflow ports are positioned on the first outer side surface provided with the power connector and communicate with the primary flow path and the secondary flow path, respectively. The two outflow ports are positioned on the first outer side surface provided with the power connector, and communicate with the primary flow path and the secondary flow path, respectively. At least one of the two inflow ports and at least one of the two outflow ports are opposite to each other across the power connector in the first direction in the plan view.

The above and other elements, features, steps, characteristics and advantages of the present disclosure will become more apparent from the following detailed description of the example embodiments with reference to the attached drawings.

### BRIEF DESCRIPTION OF THE DRAWINGS

FIG. 1 is a schematic view of a cooling device including a CDU according to an example embodiment.

FIG. 2 is a schematic perspective view of the cooling device including the CDU according to an example embodiment.

FIG. 3 is a schematic perspective view of the CDU according to an example embodiment.

FIG. 4 is a schematic perspective view showing an inside of the CDU according to an example embodiment.

FIG. 5 is a schematic perspective view showing the inside of the CDU according to an example embodiment.

FIG. 6 is a schematic front view of the CDU according to an example embodiment.

FIG. 7 is a schematic side view of the CDU according to an example embodiment.

FIG. 8 is a schematic plan view showing the inside of the CDU according to an example embodiment.

FIG. 9 is an exploded perspective view showing a configuration of the CDU according to an example embodiment.

FIG. 10 is a schematic back view of the CDU according to an example embodiment.

FIG. 11A is a schematic back view of the CDU according to an example embodiment.

FIG. 11B is a schematic plan view of the CDU according to an example embodiment.

FIG. 12A is a sectional view taken along line X-X of FIG. 7.

FIG. 12B is a sectional view taken along line XI-XI of FIG. 7.

FIG. 12C is a sectional view taken along line XII-XII of FIG. 7.

FIG. 13 is a perspective view showing a pump assembly according to an example embodiment and peripheral members thereof.

FIG. 14A is a perspective view showing the pump assembly according to an example embodiment.

FIG. 14B is a perspective sectional view showing a fitting portion between the pump assembly according to an example embodiment and a housing.

FIG. 15A is a perspective sectional view showing a handle action portion of the pump assembly according to an example embodiment.

FIG. 15B is a perspective sectional view showing a restriction state of the pump assembly according to an example embodiment.

FIG. 16 is a perspective view showing the restriction state of the pump assembly according to an example embodiment.

FIG. 17A is a perspective view showing an injection hole according to an example embodiment and peripheral components thereof.

FIG. 17B is a plan view showing a tank according to an example embodiment.

FIG. 17C is a sectional view taken along line XVII-XVII of FIG. 17B.

FIG. 18A is a perspective view showing a configuration of a control unit according to an example embodiment.

FIG. 18B is a schematic sectional view showing a holding portion of the control unit according to an example embodiment and peripheral members thereof.

FIG. 19A is a view for describing a procedure of insertion/removal of the control unit according to an example embodiment.

FIG. 19B is a view for describing the procedure of insertion/removal of the control unit according to an example embodiment.

FIG. 19C is a view for describing the procedure of insertion/removal of the control unit according to an example embodiment.

FIG. 19D is a view for describing the procedure of insertion/removal of the control unit according to an example embodiment.

FIG. 20A is a schematic perspective view of the control unit according to an example embodiment and peripheral components thereof.

FIG. 20B is a schematic perspective view of the control unit according to an example embodiment and peripheral components thereof.

FIG. 21A is a schematic plan view of a power connector according to an example embodiment and peripheral members thereof.

FIG. 21B is a schematic plan view of the power connector according to an example embodiment and peripheral members thereof.

FIG. 21C is a schematic plan view of the power connector according to an example embodiment and peripheral members thereof.

FIG. 22 is a view describing an example of information displayed on a touch screen according to an example embodiment.

FIG. 23 is a perspective view showing a liquid outflow port according to an example embodiment and peripheral members thereof.

FIG. 24 is a schematic sectional view of the CDU according to an example embodiment.

FIG. 25A is a perspective view showing a CDU locking protrusion according to an example embodiment and peripheral members thereof.

FIG. 25B is a plan view showing the CDU locking protrusion according to an example embodiment and peripheral members thereof.

### DETAILED DESCRIPTION

Hereinafter, example embodiments of refrigerant circulation devices, cooling devices, and pump assemblies according to the present disclosure will be described in detail with reference to the drawings. Note that the present disclosure is not limited by the example embodiments described herein. Each example embodiment can be appropriately combined within a range in which the processing contents do not contradict each other. In the following example embodiments, the same structural elements, features, characteristics, steps, functions, etc., are denoted by the same reference numerals, and redundant description will be omitted.

In each of the drawings to be referred to below, an orthogonal coordinate system in which an X axis direction, a Y axis direction, and a Z axis direction orthogonal to one another are defined and the Z axis direction is a vertically upward direction may be shown for easy understanding of the description.

In the following description, the Y axis direction corresponds to the “first direction”, the X axis direction corresponds to the “second direction”, and the Z axis direction corresponds to the “third direction”. For example, the X axis direction and the Y axis direction are horizontal directions. The Z axis direction is an up-down direction.

The following description assumes that each of the X axis direction, the Y axis direction, and the Z axis direction includes an error range (e.g., a range of about ±45° allowable in the technical field to which the present disclosure belongs. As an example, “extending in the X axis direction” includes not only extending in the X axis direction in a strict sense, but also extending in a direction shifted by a range of about ±45° with respect to the X axis direction.

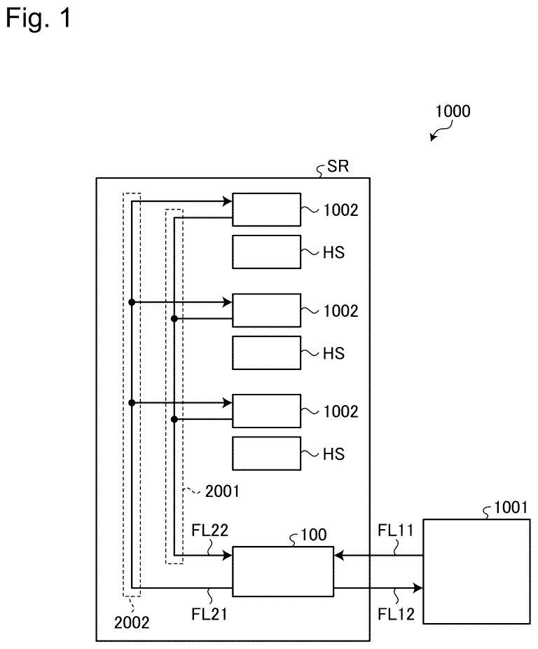

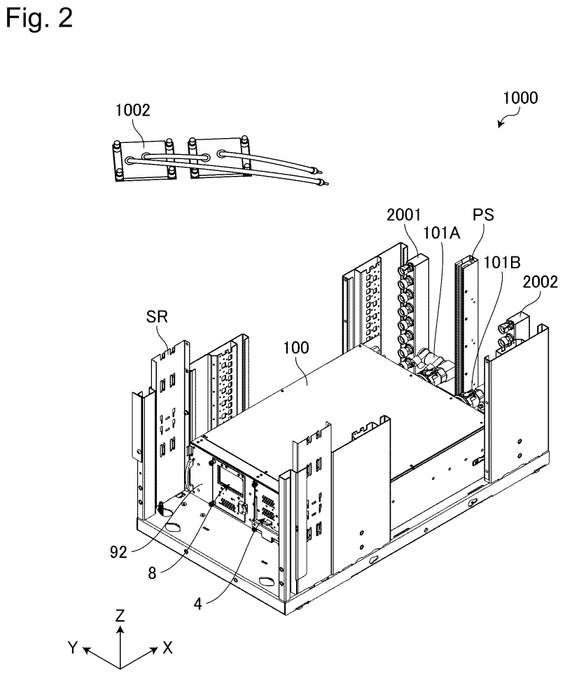

First, a cooling device 1000 according to an example embodiment will be described with reference to FIGS. 1 and 2. FIG. 1 is a schematic view of the cooling device 1000 including a CDU 100 according to the example embodiment. FIG. 2 is a schematic perspective view of the cooling device 1000 including the CDU 100 according to the example embodiment. Note that “CDU” is an abbreviation for “coolant distribution unit”.

The cooling device 1000 cools a heat source HS. For example, the heat source HS is a rack mounted server, a blade server, or the like, and is arranged inside a server rack SR. The heat source HS may be an electronic device different from the server, such as a projector, a personal computer, and a display. The heat source HS may be an electronic component such as a CPU, an electrolytic capacitor, a power semiconductor module, or a printed circuit board.

The cooling device 1000 includes the CDU 100. The CDU 100 is an example of a refrigerant circulation device. The CDU 100 is arranged inside the server rack SR. However, the present disclosure is not limited to this. The CDU 100 may be arranged outside the server rack SR.

The CDU 100 controls the temperature or the water distribution destination of the refrigerant supplied from a facility side. The CDU 100 sucks the primary refrigerant to the inside of the CDU 100 and pumps the primary refrigerant to the outside of the CDU 100. The CDU 100 sucks the secondary refrigerant to the inside of the CDU 100 and pumps the secondary refrigerant to the outside of the CDU 100. Since the inside of the CDU 100 is not provided with a pump on the primary refrigerant side, suction and pumping of the primary refrigerant in the CDU 100 are performed by an external pump. The CDU 100 performs heat exchange between the primary refrigerant and the secondary refrigerant. For example, refrigerant liquids such as antifreeze and pure water can be used as the primary refrigerant and the secondary refrigerant. Examples of the antifreeze usable as a refrigerant include an ethylene glycol aqueous solution and a propylene glycol aqueous solution. The types of the primary refrigerant and the secondary refrigerant may be the same as or may be different from each other. At least one of the primary refrigerant and the secondary refrigerant may be a gas refrigerant.

The CDU 100 is connected to flow paths FL11 and FL12. The CDU 100 sucks the primary refrigerant flowing through the flow path FL11 and pumps the primary refrigerant to the flow path FL12. The CDU 100 is connected to flow paths FL21 and FL22. The CDU 100 pumps the secondary refrigerant to the flow path FL21 and sucks the secondary refrigerant flowing through the flow path FL22.

A low-temperature primary refrigerant flows into the CDU 100. A high-temperature secondary refrigerant flows into the CDU 100. Inside the CDU 100, heat exchange is performed between the low-temperature primary refrigerant and the high-temperature secondary refrigerant. This cools the high-temperature secondary refrigerant.

The cooling device 1000 includes a cooling unit 1001. The cooling unit 1001 cools the primary refrigerant. The cooling unit 1001 may be a device installed indoors or an outdoor facility such as a cooling tower. The cooling unit 1001 is connected to the flow path FL11. The cooling unit 1001 pumps the primary refrigerant to the CDU 100 via the flow path FL11. The cooling unit 1001 is connected to the flow path FL12. The cooling unit 1001 sucks the primary refrigerant from the CDU 100 via the flow path FL12.

The cooling device 1000 includes a plurality of cold plates 1002. The cold plates 1002 are connected to the flow paths FL21 and FL22. The cold plate 1002 has an internal flow path. The internal flow path of the cold plate 1002 extends from a connection point with the flow path FL21 and reaches a connection point with the flow path FL22. That is, the secondary refrigerant is distributed inside the cold plate 1002.

The cold plate 1002 is in thermal contact with the heat source HS. The cold plate 1002 may be in direct contact with the heat source HS or may be in indirect contact with the heat source HS via a heat transfer member such as a heat transfer sheet.

When the cold plate 1002 and the heat source HS are in thermal contact with each other, thermal energy of the heat source HS is transferred to the secondary refrigerant distributed inside the cold plate 1002. As a result, the heat source HS is cooled. The secondary refrigerant used for cooling of the heat source HS flows into the CDU 100 via the flow path FL22.

The same number (i.e., a plurality of) of cold plates 1002 as the number of heat sources HS installed are installed in the server rack SR. The cold plates 1002 come into thermal contact with the heat sources HS one by one.

As shown in FIG. 1, when the number of heat sources HS installed in the server rack SR is plural, for example, a part of the flow path FL21 is constituted by a distribution manifold 2002, and a part of the flow path FL22 is constituted by a collection manifold 2001.

The collection manifold 2001 communicates with the plurality of cold plates 1002. The collection manifold 2001 has a plurality of inflow ports and one outflow port. The inflow ports of the collection manifold 2001 are connected to the cold plates 1002 different from one another. The secondary refrigerant flowing out of the cold plates 1002 flows into the collection manifold 2001 via the inflow ports of the collection manifold 2001. The outflow port of the collection manifold 2001 is connected to the CDU 100. Due to this, the secondary refrigerant flowing out of the cold plates 1002 flows into the CDU 100.

The distribution manifold 2002 communicates with the plurality of cold plates 1002. The distribution manifold 2002 has one inflow port and a plurality of outflow ports. The secondary refrigerant flows into the inflow port of the distribution manifold 2002 from the CDU 100. The secondary refrigerant flowing in from the inflow port of the distribution manifold 2002 flows out from each outflow port of the distribution manifold 2002. The outflow ports of the distribution manifold 2002 are connected to the cold plates 1002 different from one another. Due to this, the secondary refrigerant flows into the cold plates 1002. The arrangement of the collection manifold 2001 and the distribution manifold 2002 will be described later.

FIG. 1 shows a case where the number of cold plates 1002 installed (i.e., the number of heat sources HS installed) is 3. In FIG. 1, a distribution direction of each refrigerant is indicated by an arrow orientation.

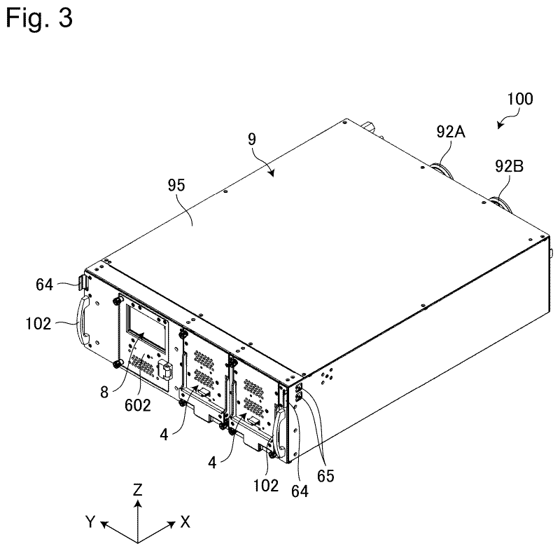

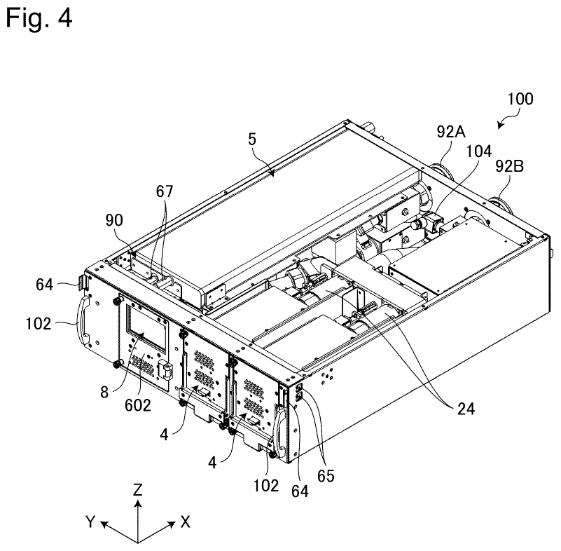

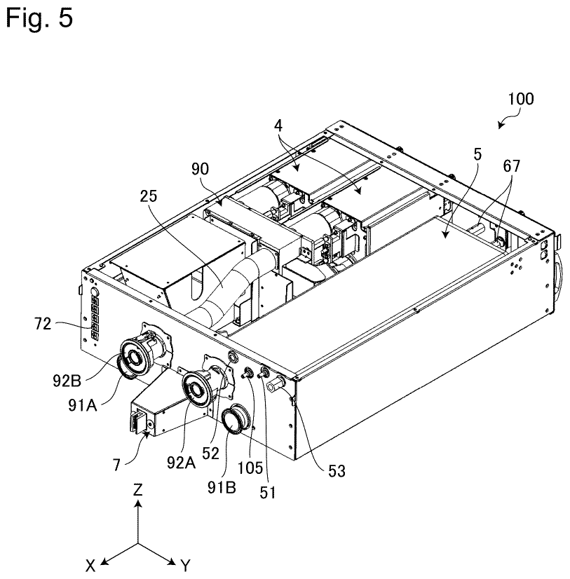

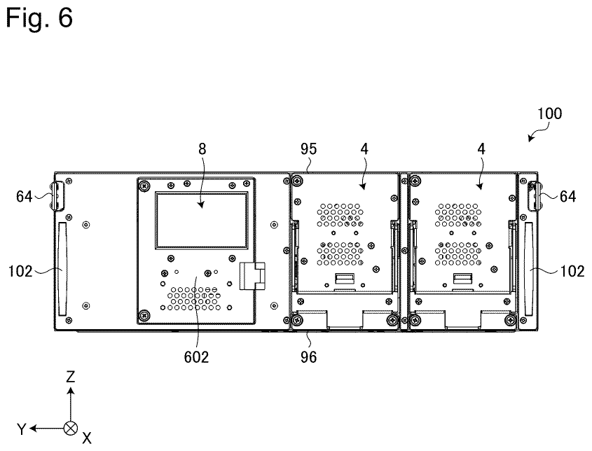

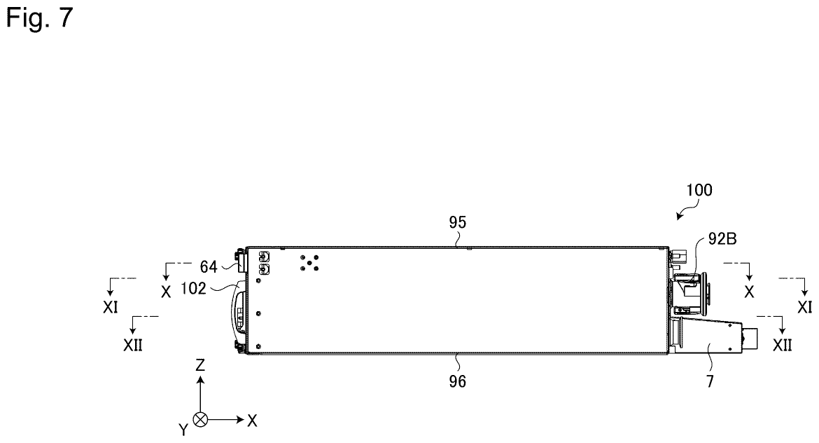

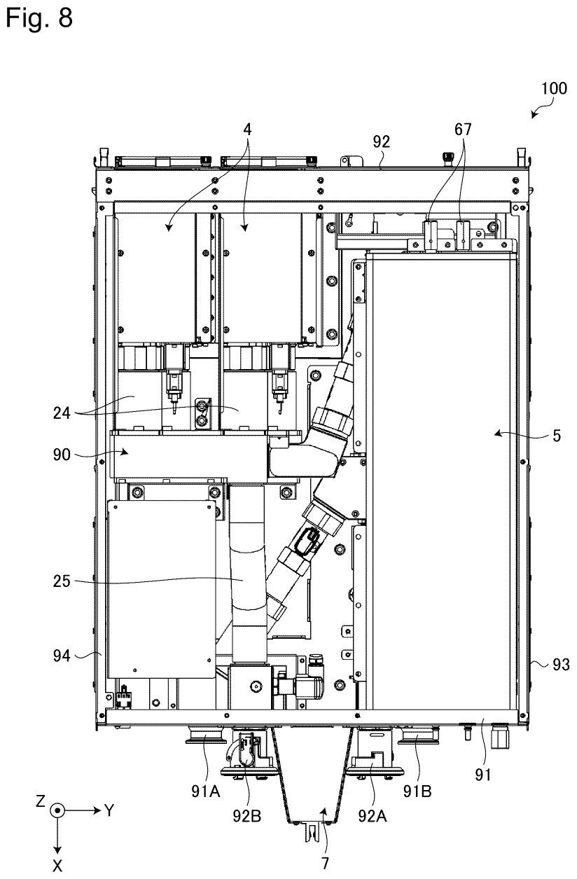

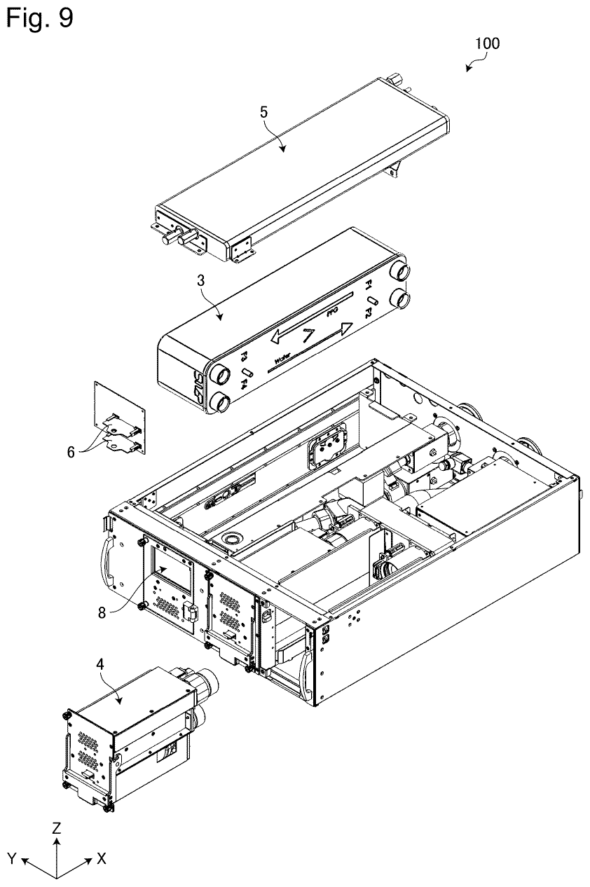

Next, the configuration of the CDU 100 according to an example embodiment will be described with reference to FIGS. 3 to 9. FIG. 3 is a schematic perspective view of the CDU 100 according to the example embodiment. FIGS. 4 and 5 are schematic perspective views showing the inside of the CDU 100 according to the example embodiment. FIG. 6 is a schematic front view of the CDU 100 according to the example embodiment. FIG. 7 is a schematic side view of a CDU 100 according to the example embodiment. FIG. 8 is a schematic plan view showing the inside of the CDU 100 according to the example embodiment. FIG. 9 is an exploded perspective view showing the configuration of the CDU 100 according to the example embodiment.

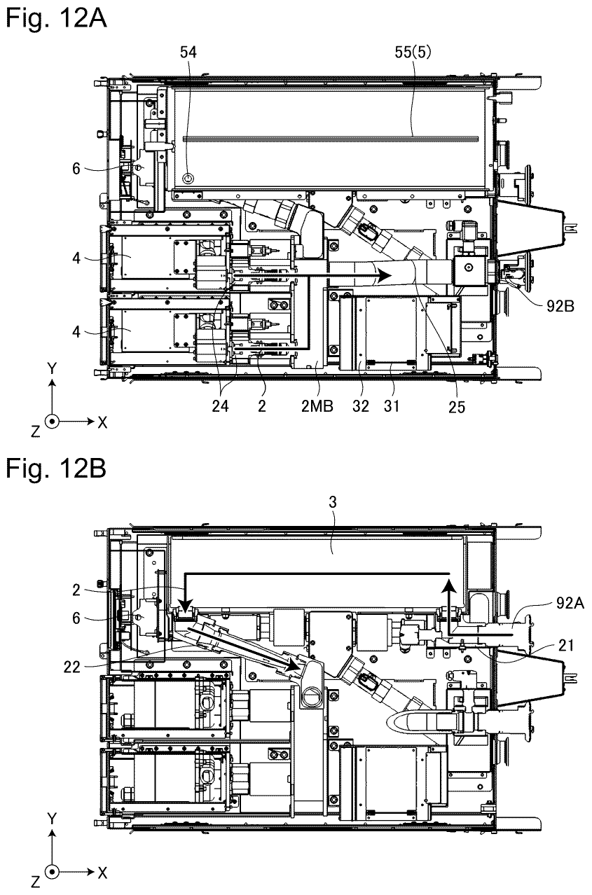

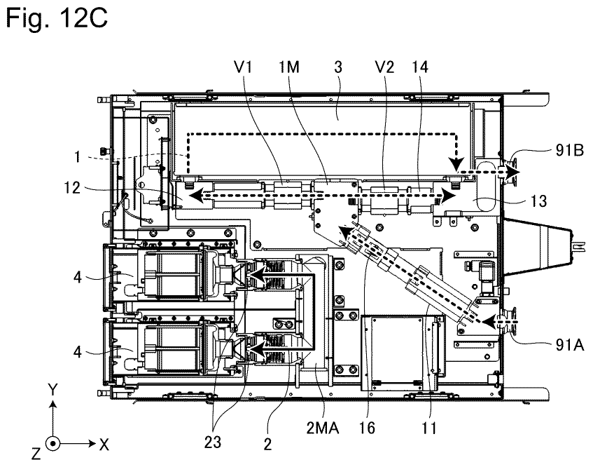

The CDU 100 includes a primary flow path 1 (see FIG. 12C) and a secondary flow path 2 (see FIG. 12B). The primary refrigerant flows through the primary flow path 1. The secondary refrigerant flows through the secondary flow path 2.

The CDU 100 includes a heat exchanger 3. The heat exchanger 3 is connected to the primary flow path 1 and the secondary flow path 2. The primary refrigerant and the secondary refrigerant flow into the heat exchanger 3 and flow out of the heat exchanger 3. The heat exchanger 3 exchanges heat between the primary refrigerant and the secondary refrigerant inside the heat exchanger 3. The heat exchange system of the heat exchanger 3 is a plate system, for example.

The CDU 100 includes a pump assembly 4. The pump assembly 4 is connected to the secondary flow path 2. The pump assembly 4 has an internal flow path. When the pump assembly 4 is driven, the secondary refrigerant is sucked into the internal flow path of the pump assembly 4, and the secondary refrigerant is pumped from the internal flow path of the pump assembly 4. Due to this, the secondary refrigerant circulates between the CDU 100 and the cold plate 1002. The number of pump assemblies 4 installed is not particularly limited. For example, the number of pump assemblies 4 installed is two. That is, the CDU 100 includes a plurality of pump assemblies 4.

The CDU 100 includes a tank 5. The tank 5 stores a refrigerant used as the secondary refrigerant. The tank 5 is connected to the secondary flow path 2. The tank 5 can supply the refrigerant to the secondary flow path 2.

The CDU 100 includes a control unit 6. The control unit 6 is connected to a temperature and humidity sensor arranged in the CDU 100, temperature sensors of the primary refrigerant and the secondary refrigerant, a flow rate sensor on the primary refrigerant side, and a pressure sensor 104 (see FIG. 4) on the secondary refrigerant side. The control unit 6 controls the pump assembly 4 and control valves V1 and V2 (see FIG. 12C).

The CDU 100 includes a touch screen 8. The touch screen 8 is provided in front of the CDU 100 and displays the operating status of the system, measurement values of sensors, and the like.

The CDU 100 includes a housing 9. The housing 9 has an accommodation region 90. The housing 9 accommodates the primary flow path 1, the secondary flow path 2, the heat exchanger 3, the pump assembly 4, the tank 5, the control unit 6, and the touch screen 8 in the accommodation region 90.

Next, the housing 9 of the CDU 100 according to an example embodiment will be described with reference to FIGS. 4 to 8. The accommodation region 90 has a substantially rectangular shape with the X axis direction as a long direction and the Y axis direction as a short direction in plan view from the Z axis direction. That is, the accommodation region 90 extends in the X axis direction and the Y axis direction intersecting each other, and has a longer dimension in the X axis direction than in the Y axis direction. In the accommodation region 90, the Z axis direction is a depth direction. The width (depth) in the Z axis direction of the accommodation region 90 is smaller than each width in the X axis direction and the Y axis direction of the accommodation region 90.

The housing 9 has a plurality of panels 91 to 96. The plurality of panels 91 to 96 are made of sheet metal, for example. The plurality of panels 91 to 96 surround the accommodation region 90. That is, the housing 9 has a region surrounded by the plurality of panels 91 to 96 as the accommodation region 90.

The panel 91 and the panel 92 are arranged to face each other in the X axis direction across the accommodation region 90. The panel 91 is arranged on one side in the X axis direction (X axis positive direction side). The panel 92 is arranged on the other side in the X axis direction (X axis negative direction side). That is, the panel 91 defines the accommodation region 90 by covering the accommodation region 90 from one side in the X axis direction. The panel 92 defines the accommodation region 90 by covering the accommodation region 90 from the other side in the X axis direction. The panel 91 and the panel 92 define the width of the accommodation region 90 in the X axis direction. In the following description, the panel 91 may be called a back panel 91, and the panel 92 may be called a front panel 92 to be distinguished from the other panels constituting the housing 9. The panel 91 and the panel 92 are examples of two first outer side surfaces extending along the Y axis direction.

The back panel 91 is provided with a power connector 7. Specifically, power connector 7 protrudes from back panel 91. The back panel 91 is provided with a local area network (LAN) cable connection port 72.

The front panel 92 is provided with a front handle 102.

The panel 93 and the panel 94 are arranged to face each other in the Y axis direction across the accommodation region 90. The panel 93 is arranged on one side in the Y axis direction (Y axis positive direction side). The panel 94 is arranged on the other side in the Y axis direction (Y axis negative direction side). That is, the panel 93 defines the accommodation region 90 by covering the accommodation region 90 from one side in the Y axis direction. The panel 94 defines the accommodation region 90 by covering the accommodation region 90 from the other side in the Y axis direction. The panel 93 and the panel 94 define the width of the accommodation region 90 in the Y axis direction. The panel 93 and the panel 94 are examples of two second outer side surfaces extending along the X axis direction.

The panel 95 and the panel 96 are arranged to face each other in the Z axis direction across the accommodation region 90. The panel 95 is arranged on one side in the Z axis direction (Z axis positive direction side). The panel 96 is arranged on the other side in the Z axis direction (Z axis negative direction side). That is, the panel 95 defines the accommodation region 90 by covering the accommodation region 90 from one side in the Z axis direction. The panel 96 defines the accommodation region 90 by covering the accommodation region 90 from the other side in the Z axis direction. The panels 95 and 96 define the width of the accommodation region 90 in the Z axis direction. The panel 95 serves as a lid covering the accommodation region 90 from above. The panel 96 serves as a bottom covering the accommodation region 90 from below.

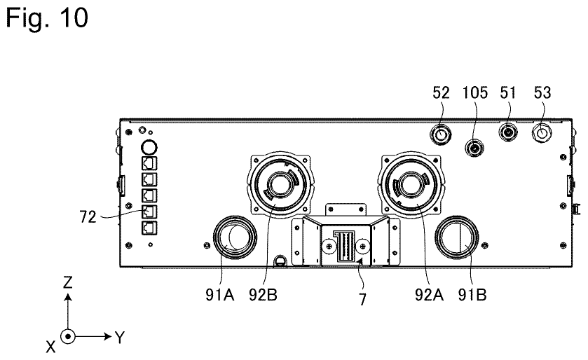

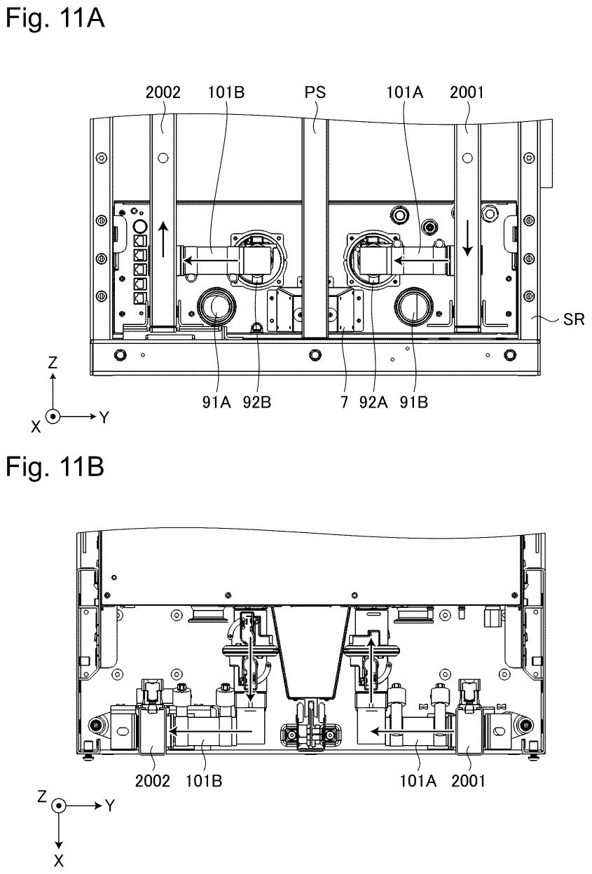

Next, inflow ports 91A and 92A and outflow ports 91B and 92B according to an example embodiment will be described with reference to FIGS. 10, 11A, and 11B. FIGS. 10 and 11A are schematic back views of the CDU 100 according to the example embodiment. FIG. 11B is a schematic plan view of the CDU 100 according to the example embodiment. FIGS. 11A and 11B show the CDU 100 in a state of being arranged in the server rack SR. In FIGS. 11A and 11B, the distribution direction of each refrigerant is indicated by an arrow orientation.

The housing 9 includes the two inflow ports 91A and 92A. Specifically, the two inflow ports 91A and 92A include a primary inflow port 91A and a secondary inflow port 92A.

The primary inflow port 91A communicates with the primary flow path 1 and serves as an inflow port of the primary refrigerant to the inside of the CDU 100. The primary inflow port 91A is connected to the flow path FL11 (see FIG. 1) extending from the cooling unit 1001. The primary refrigerant flows to the inside of the CDU 100 from the cooling unit 1001 via the primary inflow port 91A.

The secondary inflow port 92A communicates with the secondary flow path 2 and serves as an inflow port of the secondary refrigerant to the inside of the CDU 100. The secondary inflow port 92A is connected to the flow path FL22 (see FIG. 1) extending from the cold plate 1002, that is, the collection manifold 2001. The secondary refrigerant flows to the inside of the CDU 100 from the cold plate 1002 via the secondary inflow port 92A.

The housing 9 includes the two outflow ports 91B and 92B. Specifically, the two outflow ports 91B and 92B include a primary outflow port 91B and a secondary outflow port 92B.

The primary outflow port 91B communicates with the primary flow path 1 and serves as an outflow port of the primary refrigerant from the inside of the CDU 100. The primary outflow port 91B is connected to the flow path FL12 (see FIG. 1) extending from the cooling unit 1001. The primary refrigerant flows out from the inside of the CDU 100 to the cooling unit 1001 via the primary outflow port 91B.

The secondary outflow port 92B communicates with the secondary flow path 2 and serves as an outflow port of the secondary refrigerant from the inside of the CDU 100. The secondary outflow port 92B is connected to the flow path FL21 (see FIG. 1) extending from the cold plate 1002, that is, the distribution manifold 2002. The secondary refrigerant flows out from the inside of the CDU 100 to the cold plate 1002 via the secondary outflow port 92B.

The two inflow ports 91A and 92A and the two outflow ports 91B and 92B are arranged on the back panel 91. For example, back panel 91 has four openings penetrating in the X axis direction. From each of the four openings, a tubular member having the X axis direction as an axial direction protrudes to one side in the X axis direction (X axis positive direction side) relative to the back panel 91. The housing 9 has four tubular members protruding from the back panel 91 to one side in the X axis direction as the primary inflow port 91A, the primary outflow port 91B, the secondary inflow port 92A, and the secondary outflow port 92B, respectively.

Here, as described above, when the power connector 7, the two inflow ports 91A and 92A, and the two outflow ports 91B and 92B are arranged on the back panel 91, routing of pipes through which the refrigerant flows becomes complicated, and the plurality of pipes and the power connector 7 may interfere with each other. Specifically, there is a possibility that the power connector 7 interferes with the four pipes including a pipe connecting the primary inflow port 91A and the cooling unit 1001 (see FIG. 1), a pipe connecting the primary outflow port 91B and the cooling unit 1001, a pipe connecting the secondary inflow port 92A and the collection manifold 2001, and a pipe connecting the secondary outflow port 92B and the distribution manifold 2002.

Therefore, the CDU 100 according to an example embodiment assumes a configuration in which at least one of the two inflow ports 91A and 92A and at least one of the two outflow ports 91B and 92B are arranged opposite to each other across the power connector 7 in the Y axis direction. Specifically, the secondary inflow port 92A and the secondary outflow port 92B are arranged opposite to each other across the power connector 7 in the Y axis direction. In the example of FIG. 10, the secondary inflow port 92A is arranged on the Y axis positive direction side relative to the power connector 7. The secondary outflow port 92B is arranged on the Y axis negative direction side relative to the power connector 7.

Similarly, the primary inflow port 91A and the primary outflow port 91B are arranged opposite to each other across the power connector 7 in the Y axis direction. In the example of FIG. 10, the primary inflow port 91A is arranged on the Y axis negative direction side relative to the power connector 7. The primary outflow port 91B is arranged on the Y axis positive direction side relative to the power connector 7.

Thus, since at least one of the two inflow ports 91A and 92A and at least one of the two outflow ports 91B and 92B are arranged opposite to each other across the power connector 7 in the X axis direction, the power connector 7, the pipe connected to at least one of the two inflow ports 91A and 92A, and the pipe connected to at least one of the two outflow ports 91B and 92B are less likely to interfere with one another, and the pipe can be easily routed.

The arrangement of the secondary inflow port 92A and the secondary outflow port 92B is not limited to the example shown in FIG. 10. For example, the secondary inflow port 92A may be arranged on the Y axis negative direction side relative to the power connector 7, and the secondary outflow port 92B may be arranged on the Y axis positive direction side relative to the power connector 7. Similarly, the arrangement of the primary inflow port 91A and the primary outflow port 91B is not limited to the example shown in FIG. 10. For example, the primary inflow port 91A may be arranged on the Y axis positive direction side relative to the power connector 7, and the primary outflow port 91B may be arranged on the Y axis negative direction side relative to the power connector 7.

The two inflow ports 91A and 92A may be arranged on one side in the Y axis direction relative to the power connector 7, and the two outflow ports 91B and 92B may be arranged on the other side in the Y axis direction relative to the power connector 7.

The secondary inflow port 92A and the secondary outflow port 92B may be arranged on one side in the Z axis direction relative to the power connector 7. In the example of FIG. 10, the secondary inflow port 92A and the secondary outflow port 92B are arranged on the Z axis positive direction side relative to the power connector 7. In other words, the secondary inflow port 92A and the secondary outflow port 92B are arranged at positions closer to an upper panel 95 than the power connector 7.

Thus, since the secondary inflow port 92A and the secondary outflow port 92B are arranged on one side in the Z axis direction relative to the power connector 7, the pipes connected respectively to the secondary inflow port 92A and the secondary outflow port 92B and the power connector 7 are less likely to interfere with each other, and the pipe can be easily routed. Since the secondary inflow port 92A and the secondary outflow port 92B are arranged at positions close to the upper panel 95, it is easy for the user to work from above.

The primary inflow port 91A and the primary outflow port 91B may be arranged outside relative to the secondary inflow port 92A and the secondary outflow port 92B in the Y axis direction. In the example of FIG. 10, the primary inflow port 91A is positioned on the Y axis negative direction side relative to the secondary outflow port 92B. The primary outflow port 91B is positioned on the Y axis positive direction side relative to the secondary inflow port 92A.

According to such a configuration, the two inflow ports 91A and 92A and the two outflow ports 91B and 92B are arranged at positions not overlapping each other in the Y axis direction. Therefore, the pipes connected respectively to the two inflow ports 91A and 92A and the two outflow ports 91B and 92B are less likely to interfere with each other, and the pipes can be more easily routed. Since the distance between the secondary inflow port 92A and the collection manifold 2001 and the distance between the secondary outflow port 92B and the distribution manifold 2002 can be increased, a space for arranging a metal pipe, a pipe, or the like can be secured.

The primary inflow port 91A and the primary outflow port 91B may be arranged on the other side in the Z axis direction relative to the secondary inflow port 92A and the secondary outflow port 92B. In the example of FIG. 10, the primary inflow port 91A and the primary outflow port 91B are arranged on the Z axis negative direction side relative to the secondary inflow port 92A and the secondary outflow port 92B.

According to such a configuration, the pipes respectively connected to the primary inflow port 91A and the primary outflow port 91B and the pipes respectively connected to the secondary inflow port 92A and the secondary outflow port 92B are less likely to interfere with each other, and the pipes can be more easily routed.

The protrusion amount of the power connector 7 may be larger than the protrusion amount of the primary inflow port 91A, the secondary inflow port 92A, the primary outflow port 91B, or the secondary outflow port 92B from the back panel 91. Due to this, the tip end portion of the power connector 7 is less likely to come into contact with other members.

As shown in FIGS. 11A and 11B, the CDU 100 further includes a first liquid feed pipe 101A and a second liquid feed pipe 101B. The first liquid feed pipe 101A communicates with the secondary inflow port 92A and protrudes from the back panel 91. The second liquid feed pipe 101B communicates with the secondary outflow port 92B and protrudes from the back panel 91.

The first liquid feed pipe 101A may extend toward one side in the Y axis direction, and the second liquid feed pipe 101B may extend toward the other side in the Y axis direction. In the examples of FIGS. 11A and 11B, the first liquid feed pipe 101A extends toward the Y axis positive direction side, and the second liquid feed pipe 101B extends toward the Y axis negative direction side.

According to such a configuration, since the first liquid feed pipe 101A and the second liquid feed pipe 101B extend in a direction away from the power connector 7, the first liquid feed pipe 101A and the second liquid feed pipe 101B are less likely to interfere with each other. Therefore, complication of piping around the power connector 7 can be suppressed.

The collection manifold 2001 may be arranged on one side in the Y axis direction relative to the power connector 7, and the distribution manifold 2002 may be arranged on the other side in the Y axis direction relative to the power connector 7. In the example of FIG. 11A, the collection manifold 2001 is arranged on the Y axis positive direction side relative to the power connector 7, and the distribution manifold 2002 is arranged on the Y axis negative direction side relative to the power connector 7.

According to such a configuration, the pipe connecting the secondary inflow port 92A and the collection manifold 2001, the pipe connecting the secondary outflow port 92B and the distribution manifold 2002, and the power connector 7 are less likely to interfere with one another. The lengths of the first liquid feed pipe 101A and the second liquid feed pipe 101B can be shortened. Furthermore, as compared with a case where both the collection manifold 2001 and the distribution manifold 2002 are arranged on one side in the Y axis direction, the width in the X axis direction in the server rack SR occupied by the manifolds 2001 and 2002 can be reduced.

By arranging the manifolds 2001 and 2002 connected to the respective servers (not shown) on the back surface side of the server rack SR, it is possible to shorten the first liquid feed pipe 101A and the second liquid feed pipe 101B.

As shown in FIG. 11B, the first liquid feed pipe 101A and the second liquid feed pipe 101B may be arranged on one side in the X axis direction (X axis positive direction side) relative to the power connector 7 in the X axis direction.

The two inflow ports 91A and 92A and the two outflow ports 91B and 92B are connected to flow path pipes 11 and 21 and flow path pipes 13 and 25 (see FIGS. 12A to 12C) in the CDU 100, respectively. Connection ports of the inflow ports and the outflow ports with the flow path pipes are arranged so as not to overlap the heat exchanger 3 and the power connector 7 in the X axis direction. Specifically, the connection ports of the inflow ports and the outflow ports with the flow path pipes may be arranged between the heat exchanger 3 and the power connector 7. According to such a configuration, even if the manifolds 2001 and 2002 are arranged at any places in the Y axis direction, the lengths of the pipes can be sufficiently secured, and the workability is improved. Since the connection ports between the pipes and the CDU 100 are arranged so as not to overlap the heat exchanger 3 and the power connector 7 in the Y axis direction, the flow path pipes 11 to 13 and the flow path pipes 21 to 25 can be freely arranged in the CDU 100.

The secondary inflow port 92A and the secondary outflow port 92B may be connected to the manifolds 2001 and 2002 via ball valves. The size of the ball valve can be changed depending on the flow rate of the distributing refrigerant. When the flow rate increases, it is desirable to use a large valve to reduce pressure loss. In the present example embodiment, a 1.5 inch or 2 inch ball valve is used, but it is also possible to use a 1 inch ball valve due to housing in the server rack SR or the like.

Next, the primary flow path 1 according to an example embodiment will be described with reference to FIGS. 12A to 12C. FIG. 12A is a sectional view taken along line X-X of FIG. 7. FIG. 12B is a sectional view taken along line XI-XI of FIG. 7. FIG. 12C is a sectional view taken along line XII-XII of FIG. 7. In FIG. 12C, the primary flow path 1 is indicated by a dashed arrow. The direction in which the dashed arrow is oriented is the distribution direction of the refrigerant. As shown in FIG. 12C, the primary flow path 1 includes a manifold 1M and the flow path pipes 11 to 13. The internal space of the manifold 1M serves as a flow path of the primary refrigerant, and each internal space of the flow path pipes 11 to 13 serves as a flow path of the primary refrigerant.

The manifold 1M has one inflow port and two outflow ports. The primary refrigerant flowing in from the inflow port of the manifold 1M branches inside the manifold 1M and flows out from each of the two outflow ports of the manifold 1M.

The flow path pipe 11 has a bent portion and a straight pipe portion. The bent portion of the flow path pipe 11 is an elbow that bends the distribution direction of the primary refrigerant by about 45° from the X axis direction to the Y axis direction. The bent portion of the flow path pipe 11 is connected to the straight pipe portion of the flow path pipe 11. The straight pipe portion of the flow path pipe 11 extends obliquely with respect to the X axis direction. One side in the X axis direction (X axis positive direction side) of the straight pipe portion of the flow path pipe 11 is connected to the bent portion of the flow path pipe 11. The other side in the X axis direction (X axis negative direction side) of the straight pipe portion of the flow path pipe 11 is connected to the inflow port of the manifold 1M. The flow path pipe 11 causes the primary refrigerant flowing in from the primary inflow port 91A to flow in the inflow port of the manifold 1M.

The flow path pipe 12 has a straight pipe portion and a bent portion. The straight pipe portion of the flow path pipe 12 extends linearly in the X axis direction. One side in the X axis direction (X axis positive direction side) of the straight pipe portion of the flow path pipe 12 is connected to one of the outflow ports of the manifold 1M. The other side in the X axis direction (X axis negative direction side) of the straight pipe portion of the flow path pipe 12 is connected to the bent portion of the flow path pipe 12. The bent portion of the flow path pipe 12 is an elbow that bends the distribution direction of the primary refrigerant by 90° from the X axis direction to the Y axis direction. The bent portion of the flow path pipe 12 is connected to the heat exchanger 3 in the Y axis direction. The bent portion of the flow path pipe 12 bends, by 90° in the Y axis direction, the primary refrigerant distributed in the X axis direction through the straight pipe portion of the flow path pipe 12, and causes the primary refrigerant to flow into the heat exchanger 3.

The flow path pipe 13 is an elbow that bends the distribution direction of the primary refrigerant by 90° from the Y axis direction to the X axis direction. The flow path pipe 13 is connected to the heat exchanger 3 in the Y axis direction and is connected to the primary outflow port 91B in the X axis direction. The flow path pipe 13 bends, by 90° in the X axis direction, the primary refrigerant flowing in the Y axis direction from the heat exchanger 3, and flows out to the primary outflow port 91B.

The primary flow path 1 further includes a bypass pipe 14. Of the two outflow ports of the manifold 1M, the outflow port different from the outflow port connected to the flow path pipe 12 is connected to the flow path pipe 13 via the bypass pipe 14. The bypass pipe 14 causes the primary refrigerant to flow from the manifold 1M to the flow path pipe 13.

The flow path pipe 12 is provided with the control valve V1 that controls the flow rate of the primary refrigerant in the flow path pipe 12. The bypass pipe 14 is provided with the control valve V2 that controls the flow rate of the primary refrigerant in the bypass pipe 14. In this configuration, the amount of the primary refrigerant flowing into the heat exchanger 3 can be adjusted by controlling the opening degrees of the control valves V1 and V2. That is, the heat exchange performance between the primary refrigerant and the secondary refrigerant in the heat exchanger 3 can be adjusted.

The control valves V1 and V2 are, for example, electromagnetic two-way valves. The opening degrees of the control valves V1 and V2 can be adjusted by the control unit 6.

Although the example of including the control valves V1 and V2 as the two two-way valves has been described here, the number of control valves is not limited to this. For example, the bypass pipe 14 can be used by using one three-way valve in place of the two control valves V1 and V2. This can reduce the number of control valves to be used, and can reduce the cost.

Use of one two-way valve without providing the bypass pipe 14 and controlling the opening degree of the two-way valve enables adjustment of the amount of the primary refrigerant flowing into the heat exchanger 3. However, when the opening degree of the control valve is lowered, a water hammer phenomenon may occur.

Although not shown, the inside of the flow path of the primary refrigerant in the CDU 100 can include a temperature sensor and a flow rate sensor.

Next, the secondary flow path 2 according to an example embodiment will be described with reference to FIGS. 12A to 12C. In FIGS. 12A to 12C, the secondary flow path 2 is indicated by a solid arrow. The direction indicated by the arrow is the distribution direction of the refrigerant. The secondary flow path 2 is classified into an inlet side (see FIGS. 12B and 12C) and an outlet side (see FIG. 12A). On the inlet side of the secondary flow path 2, the secondary refrigerant is guided from the secondary inflow port 92A to the heat exchanger 3, and the secondary refrigerant is guided from the heat exchanger 3 to the pump assembly 4. On the outlet side of the secondary flow path 2, the secondary refrigerant is guided from the pump assembly 4 to the secondary outflow port 92B. Hereinafter, the secondary flow path 2 will be described separately on the inlet side and the outlet side.

As shown in FIGS. 12B and 12C, the inlet side of the secondary flow path 2 is configured by a manifold 2MA and the flow path pipes 21 to 23. The internal space of the manifold 2MA serves as a flow path of the secondary refrigerant, and each internal space of the flow path pipes 21 to 23 serves as a flow path of the secondary refrigerant.

The manifold 2MA has one inflow port and a plurality of outflow ports. The number of outflow ports of the manifold 2MA is the same as the number of pump assemblies 4 installed. If the number of pump assemblies 4 installed is two, the manifold 2MA has two outflow ports. The secondary refrigerant flowing in from one inflow port of the manifold 2MA branches inside the manifold 2MA and flows out from each of the plurality of outflow ports of the manifold 2MA.

The flow path pipe 21 is an elbow that bends the distribution direction of the secondary refrigerant by 90° from the X axis direction to the Y axis direction. The flow path pipe 21 is connected to the secondary inflow port 92A in the X axis direction and is connected to the heat exchanger 3 in the Y axis direction. The flow path pipe 21 bends, by 90° in the Y axis direction, the secondary refrigerant flowing X axis direction from the secondary inflow port 92A and causes the secondary refrigerant to flow into the heat exchanger 3.

The flow path pipe 22 has a bent portion and a straight pipe portion. The bent portion of the flow path pipe 22 is an elbow that bends the distribution direction of the secondary refrigerant by about 45° from the Y axis direction to the X axis direction. The bent portion of the flow path pipe 22 is connected to the straight pipe portion of the flow path pipe 22. The straight pipe portion of the flow path pipe 22 extends obliquely with respect to the X axis direction. One side in the X axis direction (X axis positive direction side) of the straight pipe portion of the flow path pipe 22 is connected to the inflow port of the manifold 2MA. The other side in the X axis direction (X axis negative direction side) of the straight pipe portion of the flow path pipe 22 is connected to the heat exchanger 3. The flow path pipe 22 causes the secondary refrigerant flowing in from the heat exchanger 3 to flow in the inflow port of the manifold 2MA.

The flow path pipe 23 is allocated to the pump assembly 4 one by one. Each flow path pipe 23 is a straight pipe extending in the X axis direction. End portions on one side in the X axis direction (X axis positive direction side) of the flow path pipes 23 are connected to the outflow ports of the manifold 2MA different from one another. End portions on the other side in the X axis direction (X axis negative direction side) of the flow path pipes 23 are connected to the corresponding pump assemblies 4. Each flow path pipe 23 causes the secondary refrigerant to flow into the corresponding pump assembly 4 from the manifold 2MA.

As shown in FIG. 12A, the outlet side of the secondary flow path 2 is configured by the manifold 2MB, the flow path pipe 24, and the flow path pipe 25. The manifold 2MB has a plurality of inflow ports and one outflow port. The number of inflow ports of the manifold 2MB is the same as the number of pump assemblies 4 installed. If the number of pump assemblies 4 installed is two, the manifold 2MB has two inflow ports. The secondary refrigerants flowing in from the plurality of inflow ports of the manifold 2MB merge inside the manifold 2MB, and flow out from one outflow port of the manifold 2MB.

The flow path pipe 24 is allocated to the pump assembly 4 one by one. Each flow path pipe 24 is a straight pipe extending linearly in the X axis direction. End portions on one side in the X axis direction (X axis positive direction side) of the flow path pipes 24 are connected to the inflow ports of the manifold 2MB different from one another. End portions on the other side in the X axis direction (X axis negative direction side) of the flow path pipes 24 are connected to the corresponding pump assemblies 4. Each flow path pipe 24 causes the secondary refrigerant to flow into the manifold 2MB from the corresponding pump assembly 4.

The flow path pipe 25 is a straight pipe extending linearly in the X axis direction. An end portion on one side in the X axis direction (X axis positive direction side) of the flow path pipe 25 is connected to the secondary outflow port 92B. An end portion on the other side in the X axis direction (X axis negative direction side) of the flow path pipe 25 is connected to the outflow port of the manifold 2MB. The flow path pipe 25 causes the secondary refrigerant to flow from the outflow port of the manifold 2MB to the secondary outflow port 92B. Due to this, the secondary refrigerant flows out from the secondary outflow port 92B, and flows in the cooling unit 1001 (see FIG. 1).

Although not shown, the inside of the flow path of the secondary refrigerant in the CDU 100 can include a temperature sensor and a flow rate sensor. In particular, by measuring the temperature of the refrigerant after flowing out of the heat exchanger 3, it is possible to grasp the temperature of the refrigerant flowing to each server, and possible to estimate the cooling performance.

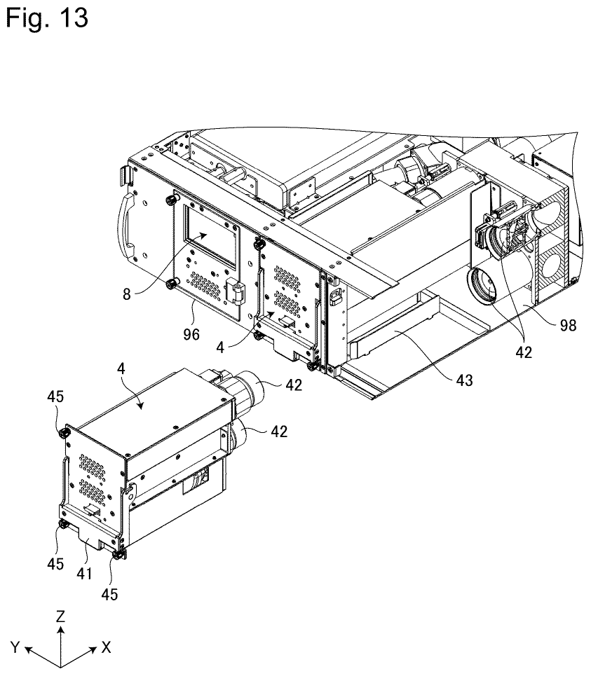

Next, the pump assembly 4 according to an example embodiment will be described with reference to FIG. 13. FIG. 13 is a perspective view showing the pump assembly 4 according to an example embodiment and peripheral members thereof.

Each pump assembly 4 is insertably/removably connected to the CDU 100. Since the pump assembly 4 and the CDU 100 are connected via a coupling 42, it is possible to suppress the refrigerant from leaking at the time of insertion/removal. Even when the refrigerant leaks due to a connection failure of the coupling 42, by providing a liquid reception tray 98 under the connection portion of the coupling 42, it is possible to suppress the refrigerant from spreading outside the device of the CDU 100. Since the connection failure of the coupling 42 occurs when the pump assembly 4 obliquely move when being inserted/removed, a guide rail 43 for moving the pump assembly 4 straight is provided.

In FIG. 13, only the lower surface of the CDU 100, that is, a bottom panel 96 is provided with one guide rail 43, but may be provided with a plurality of guide rails 43, or the guide rails 43 may be provided only on the upper surface, or on both the lower surface and the upper surface. The guide rail 43 is provided with an inclination such that the opening expands with respect to the opening portion for the pump assembly 4, and the pump assembly 4 can be easily inserted.

By providing the coupling 42 on the CDU 100 side with a floating mechanism, it is possible to absorb a small deviation of the pump assembly 4 and connect the pump assembly 4.

Since a control board (not shown) of the pump assembly 4 is arranged above the pump, even when liquid leakage occurs from the pump, a failure due to the refrigerant can be suppressed.

The pump assembly 4 includes a resin cover (not shown) that protects the control board and the wiring.

Since the upper portion of the bottom panel 96 of the CDU 100 in contact with the lower surface of the pump assembly 4 is formed by a resin plate, the pump assembly 4 can be inserted/removed with small friction. Examples of the type of the plate include PTFE and PFA.

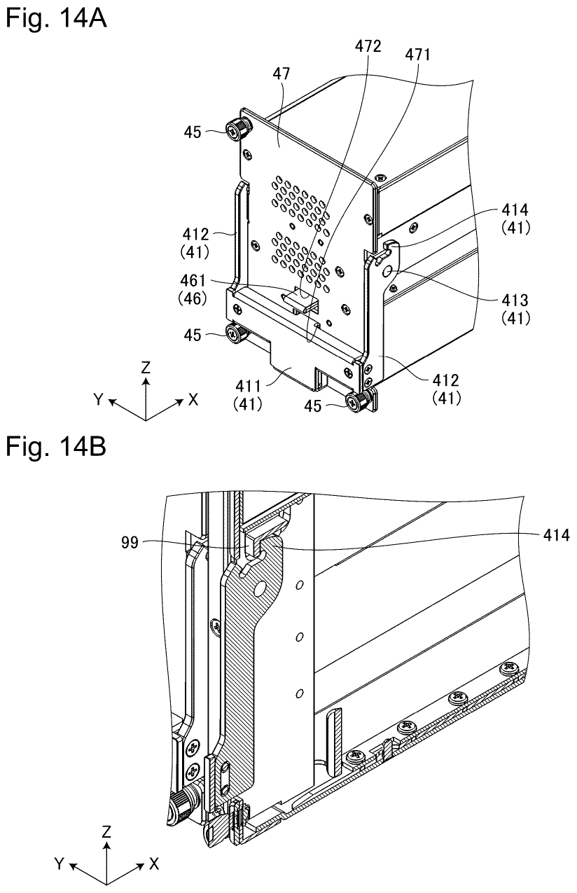

Next, a handle 41 of the pump assembly 4 according to an example embodiment will be described with reference to FIGS. 14A and 14B. FIG. 14A is a perspective view showing the pump assembly 4 according to the example embodiment. FIG. 14B is a perspective sectional view showing a fitting portion between the pump assembly 4 and the housing 9 according to the example embodiment.

As shown in FIG. 14A, the pump assembly 4 includes the handle 41. The handle 41 is an example of a movable portion. The handle 41 is rotatably fixed to both side surfaces of the pump assembly 4.

The handle 41 includes a handle action portion 411, two handle side portions 412, a rotation support portion 413, and an opposing portion 414. The handle action portion 411 is positioned outside the housing 9 in a state where the pump assembly 4 is inserted into the housing 9. Since the handle action portion 411 has a convex shape, the work is improved. Deformation due to an external force can be suppressed.

The two handle side portions 412 are positioned respectively on both side surfaces of the pump assembly 4. The two handle side portions 412 have one end portion connected to the handle action portion 411, and the other end portion fixed to the side surface of the pump assembly 4 by the rotation support portion 413. The other end portion of the handle side portion 412 is provided with the opposing portion 414 facing a protrusion portion 99 of the housing 9.

The handle 41 is displaceable between the first position and the second position. Specifically, when the handle 41 is in the first position, the two handle side portions 412 extend in the direction (X axis direction) orthogonal to a front wall 47 of the pump assembly 4, and accordingly, the handle action portion 411 is positioned on the front side (X axis negative direction side) relative to the front wall 47. On the other hand, when the handle 41 is in the second position, as shown in FIG. 14A, the two handle side portions 412 extend along both side surfaces of the pump assembly 4, and accordingly, the handle action portion 411 is positioned at the lower portion of the front wall 47. When the handle 41 is in the first position, the handle action portion 411 is positioned on the upper side (Z axis positive direction side) than when the handle 41 is in the second position. That is, when the handle 41 is in the first position, the handle 41 is in a raised state, and when the handle 41 is in the second position, the handle 41 is in a lowered state. When the handle side portion 412 rotates about a rotation axis extending along a direction (Y axis direction) intersecting the insertion/removal direction by the rotation support portion 413, the handle 41 can be displaced between the first position and the second position.

The housing 9 includes the protrusion portion 99 protruding in a direction intersecting the insertion/removal direction of the pump assembly 4.

Next, the procedure of inserting the pump assembly 4 according to an example embodiment will be described.

First, the pump assembly 4 in a state where the handle 41 is raised starts to be inserted into the CDU 100. Next, when the distance between the front panel 92 of the CDU 100 and the front wall 47 of the pump assembly 4 becomes about 10 mm, the handle 41 is lowered and inserted into the CDU 100 while pressing the pump assembly 4. At this time, the opposing portion 414 of the handle 41 comes into contact with the protrusion portion 99 of the housing 9 of the CDU 100. By lowering the handle 41, the pump assembly 4 is inserted with the protrusion portion 99 as a fulcrum.

In a state where the handle 41 is fully lowered, the opposing portion 414 is positioned on the back side in the insertion direction of the pump assembly 4 (X axis positive direction side) relative to the protrusion portion 99, and the opposing portion 414 and the protrusion portion 99 are brought into an overlapping state in the insertion/removal direction (X axis direction) of the pump assembly 4, that is, a state of facing each other, and the pump assembly 4 cannot be pulled out from the CDU 100.

When the handle 41 is fully lowered and movement of the pump assembly 4 is restricted, a fixing screw 45 is tightened at 1.5 N·m±5% in any order. Restriction of movement of the pump assembly 4 will be described later.

Since the pump assembly 4 includes the two rotation support portions 413, only one rotation support portion 413 is applied with a force by the handle operation when the handle 41 is lowered, and the pump assembly 4 is suppressed from being displaced in a direction (Y axis direction) perpendicular to the insertion/removal direction.

Next, the procedure of removal of the pump assembly 4 according to an example embodiment will be described.

First, three fixing screws 45 on the front wall 47 of the pump assembly 4 are loosened with a screwdriver in any order. Next, while holding the handle 41, an operation portion 461 is lowered and the handle 41 is raised. At this time, by pulling the handle 41 toward the front side of the CDU 100, the handle 41 rotates about the rotation support portion 413, and the handle 41 moves from the second position to the first position. This brings the opposing portion 414 of the handle side portion 412 and the protrusion portion 99 into a state of not overlapping in the insertion/removal direction of the pump assembly 4, that is, a state of not facing each other, and the pump assembly 4 can be pulled out from the CDU 100. The operation portion 461 will be described later.

When the handle 41 is fully raised, the handle action portion 411 of the pump assembly 4 is held and the pump assembly 4 is pulled out from the CDU 100.

Since there is a possibility that the CDU 100 shuts down for 10 seconds after the pump assembly 4 is pulled out, the insertion of the pump assembly 4 may be restricted. This is to suppress a circuit from being damaged due to the occurrence of a spark between terminals of an energization unit by hot swap connection at the time of insertion of the pump assembly 4. In this case, whether or not to be a state where the pump assembly 4 can be inserted can be displayed on the touch screen 8.

At the time of insertion/removal work of the pump assembly 4, the user uses an antistatic wristband. At the time of insertion/removal of the pump assembly 4, the operation or energization of the pump assembly 4 to be replaced is stopped in advance via the touch screen 8 or the like, and the pump assembly 4 is shifted to a replaceable control state.

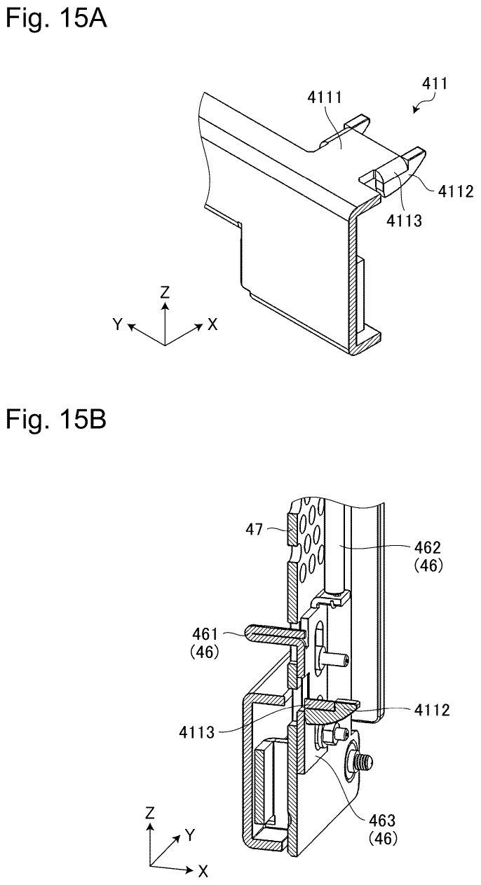

Next, restriction of movement of the pump assembly 4 according to an example embodiment will be described with further reference to FIGS. 15A, 15B, and 16. FIG. 15A is a perspective sectional view showing the handle action portion 411 of the pump assembly 4 according to the example embodiment. FIG. 15B is a perspective sectional view showing a restriction state of the pump assembly 4 according to the example embodiment. FIG. 16 is a perspective view showing a restriction state of the pump assembly 4 according to the example embodiment.

As shown in FIGS. 14A and 14B, the pump assembly 4 includes a restriction portion 46 that restricts movement of the handle 41 to the first position when the handle 41 is positioned in the second position. In other words, the restriction portion 46 restricts the handle 41 so as not to rise in a state where the handle 41 is lowered.

The restriction portion 46 includes the operation portion 461, an elastic portion 462, and a plate portion 463. The operation portion 461 can be displaced between the third position and the fourth position. Specifically, the case where the operation portion 461 is positioned in the third position is a case where the operation portion 461 is positioned on the Z axis positive direction side in a through hole 472 of the front wall 47 as shown in FIG. 14A. The case where the operation portion 461 is positioned in the fourth position is a case where the operation portion 461 is positioned on the Z axis negative direction side in the through hole 472 of the front wall 47. That is, when the operation portion 461 is in the third position, the operation portion 461 is in a raised state, and when the operation portion 461 is in the fourth position, the operation portion 461 is in a lowered state.

The elastic portion 462 biases the operation portion 461 in a direction from the fourth position toward the third position (Z axis positive direction). As shown in FIG. 15B, the plate portion 463 is connected to the operation portion 461 on the back surface side of the front wall 47 of the pump assembly 4.

The restriction portion 46 restricts the movement of the handle 41 to the first position by the operation portion 461 moving from the fourth position to the third position along with the movement of the handle 41 from the first position to the second position. On the other hand, when the operation portion 461 moves from the third position to the fourth position, the state where the movement of the handle 41 to the first position is restricted is released.

Since the CDU 100 according to the present example embodiment includes the restriction portion 46, it is possible to suppress the handle 41 from moving to the first position due to an erroneous operation and the pump assembly 4 from coming off from the CDU 100. Since the restriction portion 46 includes the operation portion 461, the state of the restriction portion 46 can be changed by a user operation.

As shown in FIG. 15A, the handle action portion 411 includes a penetration portion 4111 to be inserted into a through hole 471 provided on the front wall 47 of the pump assembly 4. The penetration portion 4111 includes an inclined portion 4112 inclined in a direction in which the penetration portion is inserted into the through hole 471 and an opposing portion 4113 having no inclination.

When the handle 41 is lowered after the pump assembly 4 is inserted into the CDU 100, the penetration portion 4111 of the handle action portion 411 is inserted into the through hole 471, and the plate portion 463 and the opposing portion 4113 face each other in the insertion/removal direction (X axis direction). This is because the operation portion 461 and the plate portion 463 are pulled upward in the vertical direction (Z axis positive direction side) by the elastic portion 462. Unless the user lowers the operation portion 461, at least a part of the plate portion 463 is brought into a state of being positioned in a position facing the through hole 471 (see FIG. 15B). Therefore, the user is suppressed from raising the handle 41. In other words, the movement of the handle 41 to the first position is restricted.

That is, when the penetration portion 4111 penetrates the through hole 471, the opposing portion 4113 and the plate portion 463 face each other in the insertion/removal direction, and therefore the penetration portion 4111 is prevented from coming off of the through hole 471 unless the user lowers the operation portion 461.

When the user lowers the operation portion 461, the elastic portion 462 extends and the plate portion 463 is also lowered and does not face the opposing portion 4113, and therefore the penetration portion 4111 can be pulled out from the through hole 471 and the handle 41 can be moved.

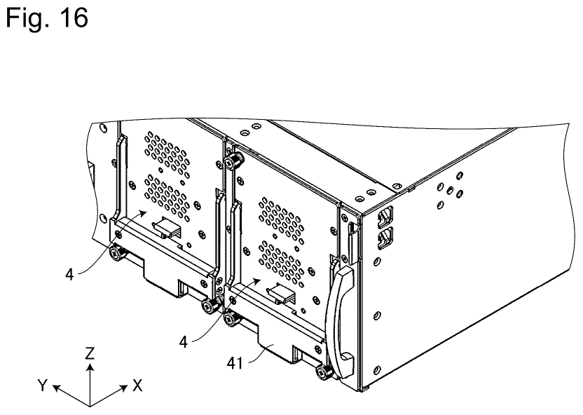

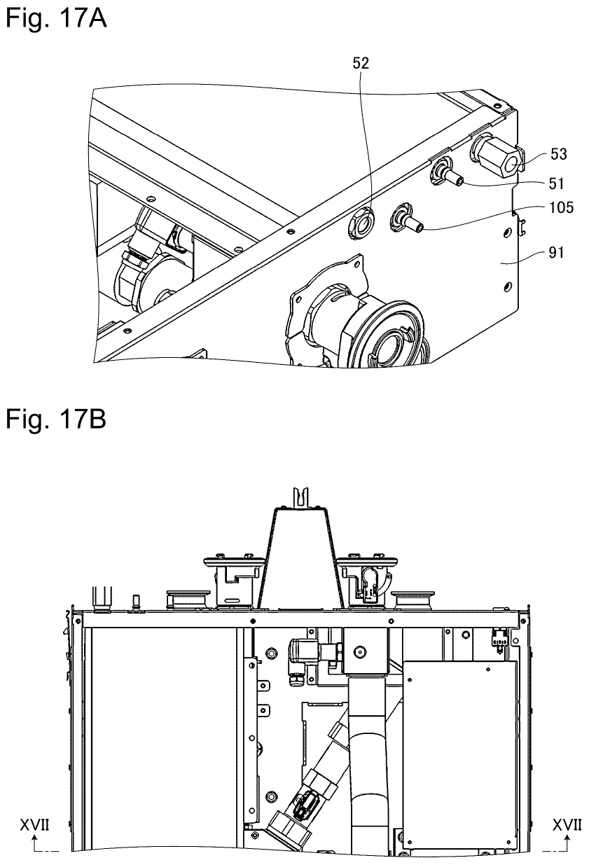

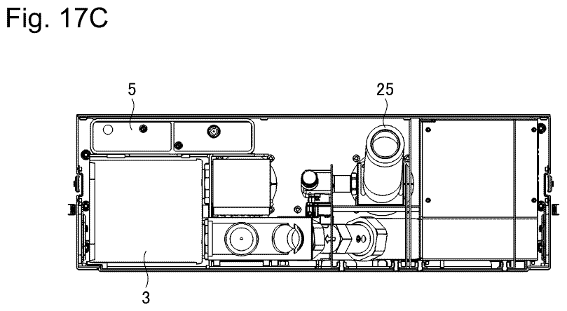

Next, an injection hole 105 and the tank 5 according to an example embodiment will be described with reference to FIGS. 17A to 17C. FIG. 17A is a perspective view showing the injection hole 105 according to an example embodiment and peripheral components thereof. FIG. 17B is a plan view showing the tank 5 according to the example embodiment. FIG. 17C is a sectional view taken along line XVII-XVII of FIG. 17B.

The CDU 100 includes the injection hole 105 for the refrigerant on the back panel 91. The injection hole 105 is connected to the secondary flow path 2 (see FIGS. 12A to 12C), and can circulate the injected refrigerant. The injection hole 105 includes a coupling, and the refrigerant can be injected by mounting the corresponding coupling.

The tank 5 includes a tank injection hole 51, an air vent valve 53, and a liquid level check window 52.

The tank injection hole 51 is mounted with a coupling corresponding to a coupling on the tank 5, and the refrigerant is injected into the tank 5.

When a gas is accumulated in the tank 5, the air vent valve 53 can release the gas to the outside by opening the air vent valve 53.

As the liquid level check window 52, by providing a window made of a material through which the inside of the tank 5 can be checked, it is possible to check the liquid level. Since it is exposed from the back panel 91 of the CDU 100, it can be checked without moving the CDU 100.

The tank 5 further includes a liquid level sensor 67 (see FIGS. 4 and 8). When the liquid level of the refrigerant in the tank 5 falls below a threshold, the liquid level sensor 67 transmits a notification to the control unit 6.

Note that the injection hole 105 and the tank injection hole 51 can be covered with a cover member or the like when not in use.

In the present example embodiment, the tank 5 can store about 3 L (volume: 564 mm*190 mm*40 mm) of refrigerant, and by increasing the storage amount of the tank 5, the frequency of resupplying the refrigerant can be reduced. The tank 5 communicates with the flow path pipe 25 of the secondary refrigerant via a hole portion (not shown) provided on the lower surface, and the refrigerant in the tank 5 is resupplied to the circulation when the circulating secondary refrigerant decreases. Due to this, the flow rate of the circulating secondary refrigerant can be kept constant.

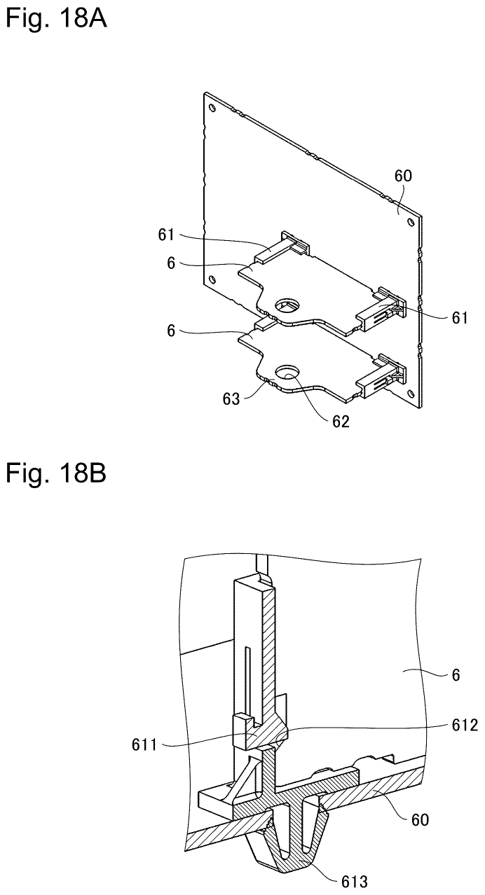

Next, the configuration of the control unit 6 according to an example embodiment will be described with reference to FIGS. 18A and 18B. FIG. 18A is a perspective view showing the configuration of the control unit 6 according to the example embodiment. FIG. 18B is a schematic sectional view showing a holding portion 61 of the control unit 6 according to an example embodiment and peripheral members thereof.

The control unit 6 controls operations of the pump assembly 4, the control valves V1 and V2 (see 22 C), and the like in the CDU 100, monitors an operation state, monitors various sensors, and communicates with external devices.

In the present example embodiment, the CDU 100 includes two control units 6. With the two control units 6, even when one of them fails, continuous operation is possible by operating the other. By enabling live wire insertion/removal of the control unit 6, it is possible to replace the failed control unit 6 while operating the CDU 100.

The control unit 6 includes a protrusion portion 63 and a knob hole portion 62 in a center upper portion, and workability at the time of replacement can be improved. By not arranging an electronic component or a circuit around the knob hole portion 62 and the protrusion portion 63, it is possible to prevent a failure due to contact with a user's hand.

By the fixing method of the control unit 6, the control unit 6 is insertably/removably fixed by providing the holding portions 61 on both sides in the long direction of the control unit 6. Even when the control unit 6 is inserted into the holding portion 61 by snap-fitting, the control unit 6 can be removed by providing an inclined portion 612 on a surface facing a claw portion 611 of the holding portion 61 of the control unit 6 from the insertion direction side. Since the operation for inserting/removing is only to move the control unit 6 up and down, the work can be performed with one hand.

As shown in FIG. 18A, a connection board 60 of the control unit 6 can be arranged substantially horizontally in the vertical direction. However, it can also be arranged in the horizontal direction. Since the length in the vertical direction of the connection board 60 when arranged in the vertical direction is shorter than the length in the vertical direction of an arrangement space in the CDU 100, it can be arranged without being in contact with the upper panel 95 and the bottom panel 96 of the CDU 100. Therefore, the vibration of the CDU 100 can be suppressed from being transmitted to the control unit 6. By arranging the connection board 60 in the vertical direction, the width in the horizontal direction can be shortened, and the arrangement space for other components can be increased.

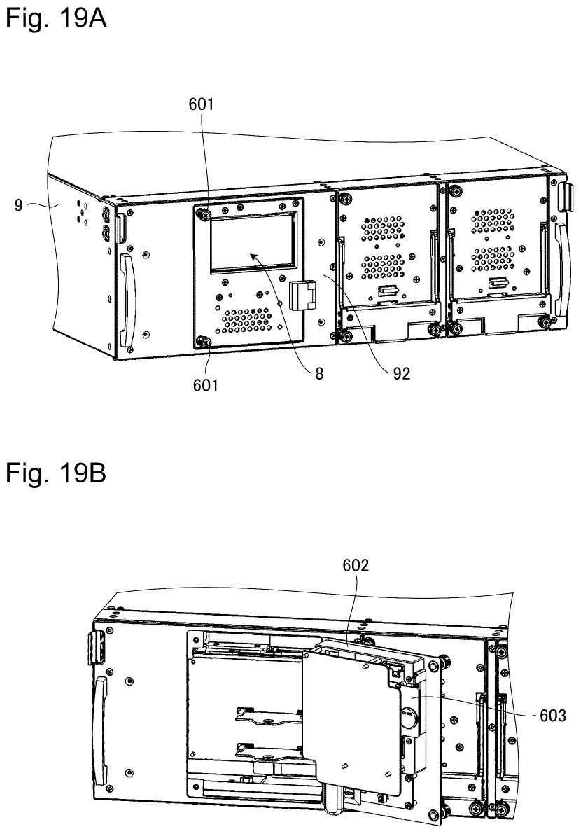

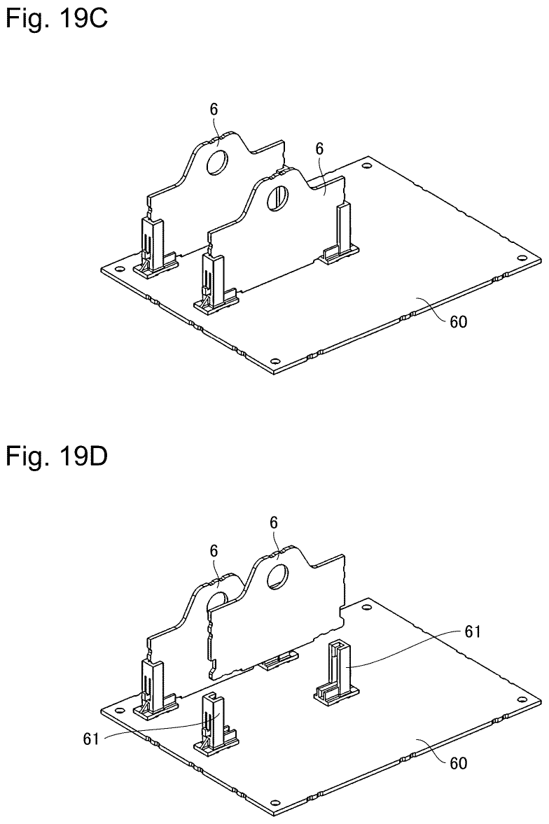

Next, the procedure of insertion/removal of the control unit 6 according to an example embodiment will be described with reference to FIGS. 19A to 19D. FIGS. 19A to 19D are views for describing the procedure of insertion/removal of the control unit 6 according to the example embodiment.

First, the position of the control unit 6 that needs to be replaced is checked from the touch screen 8 or the like (see FIG. 19A). Two control units 6 are arranged in the CDU 100, and the operating state can be checked for each control unit 6.

Next, a fixing screw 601 of the front panel 92 of the housing 9 is loosened and taken out. Next, because the touch screen 8 has an openable/closable door shape, a control unit door 602 is opened (see FIG. 19B).

Next, the knob hole portion 62 (see FIG. 18A) of the control unit 6 that needs to be replaced is grasped and pulled up (see FIG. 19C). Next, a new control unit 6 is inserted along the holding portion 61 until a click sound is generated from the holding portion 61 (see FIG. 19D). Thereafter, the control unit door 602 is closed, and the fixing screw 601 is tightened.

As shown in FIG. 19B, the connection board 60 can also be arranged in the horizontal direction. Even when the connection board 60 is arranged in the vertical direction, the procedure of insertion/removal of the control unit 6 is the same.

The touch screen 8 and a control board 603 of the touch screen 8 are insulated and fixed to the control unit door 602.

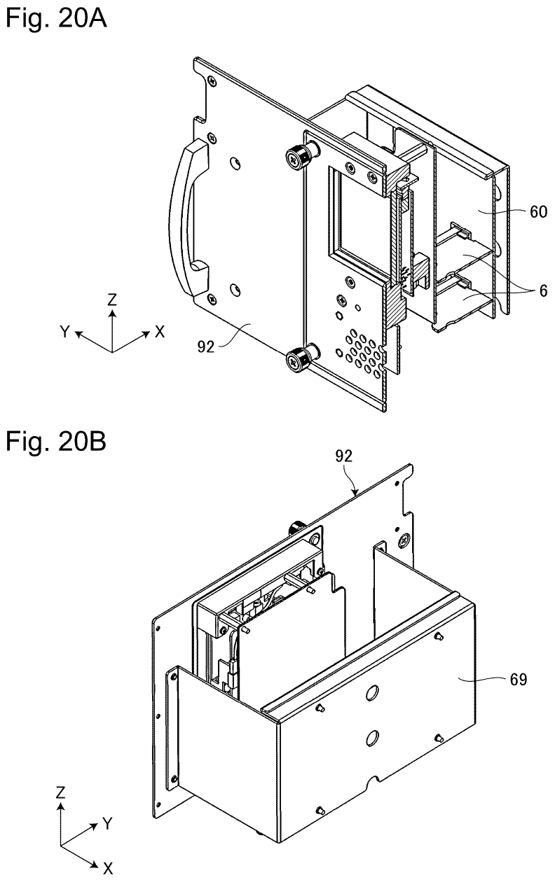

Next, the arrangement of the control unit 6 according to an example embodiment will be described with reference to FIGS. 20A and 20B. FIGS. 20A and 20B are schematic perspective views of the control unit 6 according to an example embodiment and peripheral components thereof.

The control unit 6 and the connection board 60 are connected to the front panel 92 including the touch screen 8 and assembled to the CDU 100. The connection board 60 is connected to a fixing plate 69. The fixing plate 69 is fixed to the front panel 92.

At the time of assembly work of the CDU 100, the front panel 92 is attached after the heat exchanger 3 is arranged in the CDU 100, whereby damage due to contact of the control unit 6 and the touch screen 8 with other members can be suppressed.

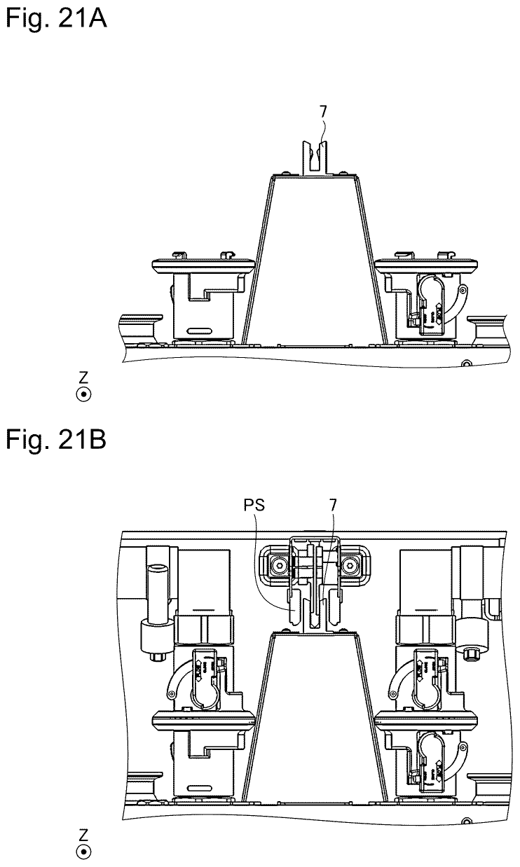

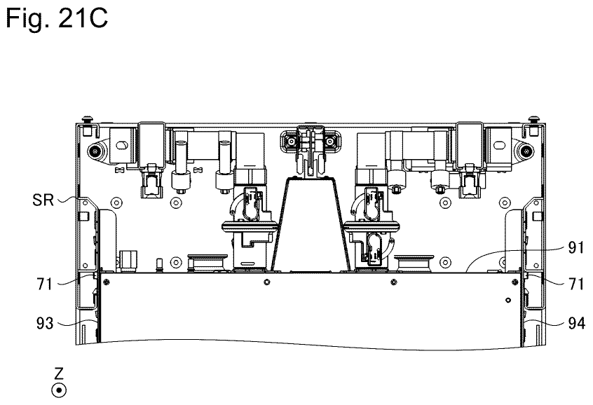

Next, the power connector 7 according to an example embodiment will be described with reference to FIGS. 21A to 21C. FIGS. 21A to 21C are schematic plan views of the power connector 7 according to an example embodiment and peripheral members thereof. Note that FIG. 21A shows the power connector 7 when not connected to a power source PS in the server rack SR, and FIGS. 21B and 21C show the power connector 7 when connected to the power source PS in the server rack SR.

The power connector 7 can be connected to the external power source PS. The CDU 100 includes the power connector 7 on the back side. The power connector 7 can supply power to the CDU 100 by being connected to the power source PS provided on the back side of the server rack SR.

As shown in FIG. 21C, the CDU 100 includes positioning protrusions 71 on both side surfaces on the back surface side. Specifically, the CDU 100 includes the positioning protrusion 71 in a position of the panel 93 close to the back panel 91. Similarly, the CDU 100 includes the positioning protrusion 71 in a position of the panel 94 close to the back panel 91. When the CDU 100 is inserted into the server rack SR, the positioning protrusion 71 comes into contact with a server (not shown), whereby it is possible to suppress the CDU 100 from being excessively inserted into the server rack SR. Therefore, it is possible to suppress breakage due to excessive contact between the power connector 7 and the power source PS.

The power connector 7 may have a trapezoidal shape in plan view. In other words, the width of the tip end portion of the power connector 7 may be narrower than the width of the base end portion of the power connector 7. Such a configuration can suppress contact between the power connector 7 and the peripheral members.

The power connector 7 can be inserted into and removed from the power source PS together with insertion into and removal from the CDU 100 from the server rack SR. The power connector 7 and the power source PS can be positioned by the positioning protrusion 71 for the depth direction.

Next, the touch screen 8 according to an example embodiment will be described. The touch screen 8 (see FIGS. 4 and 6) is provided on the front panel 92 of the CDU 100. The touch screen 8 is connected to the control unit 6 (see FIG. 20A). The control unit 6 causes the touch screen 8 to display various types of information. The touch screen 8 can display, for example, a status or control section that displays the operating status of the pump assembly 4, the temperature of the refrigerant, and the like, and a navigation menu.

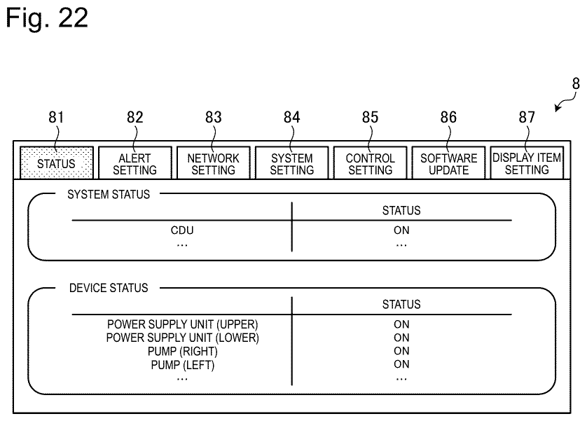

Here, an example of information displayed by the control unit 6 will be described with reference to FIG. 22. FIG. 22 shows an example of information displayed on the touch screen 8 according to the example embodiment. For example, when the user selects, by a touch operation or the like, tabs 81 to 87 displayed on the touch screen 8, the information displayed on the touch screen 8 is switched. Hereinafter, information displayed when the tabs 81 to 87 are selected or information that can be set will be described.

The status tab 81 displays detailed operation information of internal components. This includes a system status, a device status, and a sensor value (see FIG. 22).

In the alert setting tab 82, system parameters for notifying a system alert or alert status can be set. If the parameters are exceeded, an alert by a predetermined method is output. Specifically, it is possible to set parameters such as a liquid temperature of the refrigerant, temperature and humidity of a server room, a leak sensor, the refrigerant, change in flow rate, and an operating state of the pump assembly 4, the power connector 7, the control unit 6, or the control valves V1 and V2.

In the network setting tab 83, the network configuration for remote access to the CDU 100 can be checked or set.

In the system setting tab 84, for example, main body information, password, date and time, debug mode, screen saver, or the system status can be set.

In the control setting tab 85, information regarding control of the web interface and control of the operation of the CDU 100 can be set.

In the software update tab 86, software modules in the CDU 100 can be updated as needed. The software update tab 86 can only be used for network access by web browsers.

A maintenance mode for restricting items displayed on the touch screen 8 may be included. In the maintenance mode, only items and tabs to be used are displayed for each user, and information not to be used is hidden. Accordingly, the visibility that allows the user to easily search for information needed by the user is improved. For example, the maintenance mode can be switched on and off from the display item setting tab 87.

Note that the information displayed on the touch screen 8 can also be checked from an external device by connecting the CDU 100 to a network.

Next, the flow rate of the primary refrigerant and specifications of the flow rate sensor 16 will be described with reference to FIG. 12C. In the present example embodiment, the flow rate of the primary refrigerant is 150 to 170 L/min at the maximum. Note that the flow rate of the primary refrigerant can be changed in accordance with a required maximum cooling performance. For example, when it is desired to improve the maximum cooling performance as compared with the present example embodiment, the secondary refrigerant can be further cooled by increasing the flow rate of the primary refrigerant, and the cooling performance of each server is improved.

If the flow rate of the primary refrigerant is too high with respect to the required cooling performance, the pressure may increase and cause damage. Therefore, it is necessary to appropriately set the maximum refrigerant flow rate.

The maximum measurement range of the flow rate sensor 16 that is provided in the CDU 100 and measures the flow rate of the primary refrigerant is set to be larger than the maximum flow rate of the primary refrigerant. In the present example embodiment, the maximum measurement range is desirably 200 L/min or more.

Next, a power distribution board 31 according to an example embodiment will be described with reference to FIG. 12A. The power distribution board 31 supplies the pump assembly 4, the control valves V1 and V2, the sensors, and the like with electricity supplied from the power connector 7. In addition to power distribution, the power distribution board 31 can have roles such as relay between the sensors and the control unit 6 and control of the pump assembly 4.

The power distribution board 31 is arranged on the back side of the CDU 100. Therefore, the wiring for power supply from the power connector 7 to the power distribution board 31 can be shortened as compared with a case of arranging in another place. By shortening the wiring, it is possible to suppress contact with the flow path pipes 11 to 13 and the flow path pipes 21 to 25 and to take measures against noise.

The power distribution board 31 can be arranged around the control unit 6. In that case, since the space around the power connector 7 can be expanded, the degree of freedom in the arrangement design of the flow path pipes 11 to 13 and the flow path pipes 21 to 25 is improved.

By performing a waterproof treatment such as potting treatment, the prevention performance can be improved.

Next, specifications of the heat exchanger 3 according to an example embodiment will be described. The heat exchanger 3 in the present example embodiment has a size of, for example, 526 mm in width, 119 mm in depth, and 120 mm in height. The size of the heat exchanger 3 is changed depending on the required cooling performance, the flow rate of the primary refrigerant, the flow rate of the secondary refrigerant, the flow path resistance of each flow path pipe, and the like. For example, even when the same cooling performance as that of the present example embodiment is required, the size of the heat exchanger 3 can be reduced by increasing the flow rate of the primary refrigerant.

Next, specifications of the flow path pipes 11 to 13 and the flow path pipes 21 to 25 will be described with reference to FIGS. 12A to 12C. The larger the diameters of the flow path pipes 11 to 13 and the flow path pipes 21 to 25 are, the more pressure loss can be reduced, which is desirable. In order to detect leakage of the refrigerant from the flow path pipes 11 to 13 and the flow path pipes 21 to 25, the flow path pipes 11 to 13 and the flow path pipes 21 to 25 can be provided with a leak sensor (not shown).

The diameters of the flow path pipes 11 to 13 and the flow path pipes 21 to 25 can be changed depending on a place where they are arranged. In the present example embodiment, the diameters of the flow path pipes 23 and 24 are increased. The above portion includes a component as a coupler, and when the diameter is made uniform with other flow path pipes, the flow path resistance increases, and therefore the flow path resistance can be reduced by increasing the diameter. Specifically, the diameters of the flow path pipes 23 and 24 are set to 50 mm to 58 mm, and the diameters of the other flow path pipes are set to 40 mm to 48 mm.

The flow path pipes 11 and 22 arranged opposite to the heat exchanger 3 across the power connector 7 include a straight pipe portion extending obliquely with respect to the X axis direction in plan view. This can shorten the length of the primary flow path 1 or the secondary flow path 2. The flow path resistance can be suppressed as compared with the case where the flow path pipe is bent at a right angle.

The flow path pipes 11 to 13 and the flow path pipes 21 to 25 may be made of metal or resin. In the case of being made of resin, flexibility is superior to that of the metal pipe, routing is easy, and workability is excellent. In the case of metal, the connection portion is easily sealed as compared with the resin material, and the decrease in the refrigerant can be suppressed.

Next, control specifications of the control valves V1 and V2 (see FIG. 12C) according to an example embodiment will be described. In the present example embodiment, the temperature of the secondary refrigerant can be adjusted by controlling the control valves V1 and V2. The control criteria of the control valves V1 and V2 can be controlled such that, for example, the temperature of the secondary refrigerant becomes an arbitrary temperature set by the user. In another example, it is also possible to measure the dew point in the CDU 100 and control the temperature of the secondary refrigerant so as not to fall below the dew point. The control of the temperature may be based on only one of the above, or may be controlled so as to satisfy both.

Specifically, in the method of controlling the temperature of the secondary refrigerant, the flow rate of the primary refrigerant flowing into the heat exchanger 3 is decreased when it is desired to increase the temperature of the secondary refrigerant, and the flow rate of the primary refrigerant flowing into the heat exchanger 3 is increased when it is desired to decrease the temperature of the secondary refrigerant. By controlling the temperature of the refrigerant so as not to fall below the dew point, generation of water droplets in the CDU 100 can be suppressed, and damage to the control unit 6, the power distribution board 31, and the like can be suppressed. The cooling performance of the cold plate 1002 can be kept high by controlling the temperature of the secondary refrigerant to be equal to or lower than an arbitrary temperature.

Next, the liquid reception tray 98 and a liquid outflow port 97 according to an example embodiment will be described with reference to FIG. 23. FIG. 23 is a perspective view showing the liquid outflow port 97 according to an example embodiment and peripheral members thereof.

The CDU 100 further includes the liquid reception tray 98 (see FIG. 13) and the liquid outflow port 97. The liquid reception tray 98 is arranged on the bottom of the CDU 100, that is, the entire surface of the panel 96 except for a region where the inserted pump assembly 4 is arranged.

The liquid outflow port 97 is provided on the back panel 91 of the CDU 100 and is connected to the liquid reception tray 98. When the refrigerant accumulates in the liquid reception tray 98, it is possible to suppress the refrigerant from being discharged from the liquid outflow port 97 and the refrigerant from excessively accumulating in the CDU 100. The liquid reception tray 98 may have a planar shape or may be provided with an inclination toward the liquid outflow port 97. In the present example embodiment, since the liquid reception tray 98 is formed of SUS, deformation can be suppressed even if it is large. The liquid reception tray 98 can also be formed of other materials.

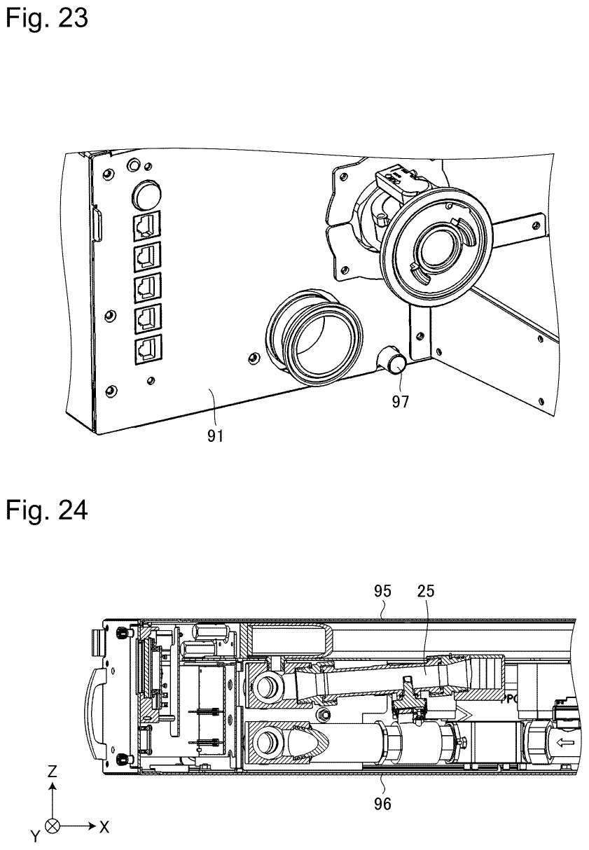

Next, specifications of the flow path pipe 25 will be described with reference to FIG. 24. FIG. 24 is a schematic sectional view of the CDU 100 according to the example embodiment.

The flow path pipe 25 flowing out from the heat exchanger 3 and extending to a branch flow path is inclined in the Z axis positive direction. Since the flow path pipe 25 is inclined in the Z axis positive direction, it is not necessary to provide an inclination in other members. The flow path pipe 25 can absorb dimensional errors in the Z axis direction, and assembly becomes easy.

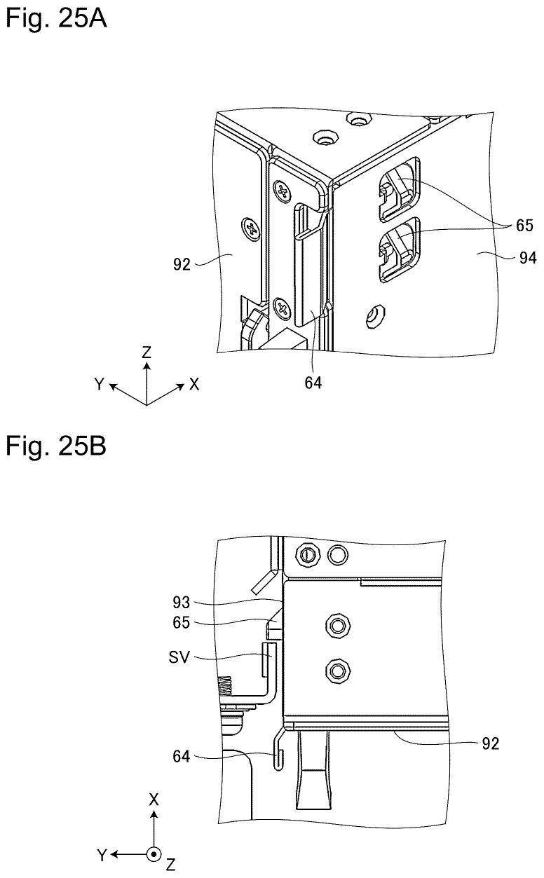

Next, a lock mechanism between the CDU 100 and a server SV will be described with reference to FIGS. 25A and 25B. FIG. 25A is a perspective view showing a CDU locking protrusion 65 according to an example embodiment and peripheral members thereof. FIG. 25B is a plan view showing the CDU locking protrusion 65 according to an example embodiment and peripheral members thereof.

The CDU 100 includes the CDU locking protrusions 65 on both side surfaces on the front side. The CDU locking protrusion 65 is displaced in an inward direction of the CDU 100 when the CDU 100 moves in the insertion direction (X axis positive direction) and comes into contact with the server SV, and thus does not prevent the CDU 100 from being inserted into the server. When the CDU 100 moves in the removal direction (X axis negative direction), the CDU locking protrusion 65 comes into contact with the server SV, and thus the removal of the CDU 100 is suppressed.

A release handle 64 is connected to the CDU locking protrusion 65. By pushing the release handle 64 in the inward direction of the CDU 100, the CDU locking protrusion 65 can also be moved inward in conjunction therewith. That is, when removing the CDU 100, it is possible to remove the CDU 100 by moving the CDU 100 in the removal direction while pushing the release handles 64 provided on both side surfaces.

Next, the arrangement of the CDU 100 according to an example embodiment will be described with reference to FIG. 2.

The CDU 100 according to an example embodiment is arranged in a lower layer of the server rack SR. When a door (not shown) of the server rack SR is opened, the front of the CDU 100, that is, the front panel 92 is arranged so that it can be checked. Therefore, the touch screen 8 and the pump assembly 4 are arranged on the front side, and the operating status of the pump assembly 4, the control unit 6 (see FIG. 12A), and the like can be checked by the touch screen 8. Since the pump assembly 4 and the control unit 6 are arranged on the front surface that can be worked without pulling out the CDU 100, the failed member can be replaced while operating without moving the CDU 100.

Since the liquid feed pipes 101A and 101B connected to the CDU 100 are arranged on the back surface side of the server rack SR, connection work of the liquid feed pipes 101A and 101B where the CDU 100 is arranged in the server rack SR can easily be performed. By arranging the manifolds 2001 and 2002 connected to the respective servers on the back surface side of the server rack SR, it is possible to connect, with a short flow path, to the liquid feed pipes 101A and 101B connected to the back surface side of the CDU 100.

In the present example embodiment, the secondary refrigerant on the server side that circulates through the cold plates 1002, the manifolds 2001 and 2002, and the CDU 100, and the primary refrigerant on the facility side that exchanges heat with the secondary refrigerant on the server side by circulating the refrigerant from the outside are included.

The front surface and the back surface of the CDU 100 are exposed to the outside from the server rack SR or can be exposed by opening/closing of the door or the like.

Next, the layout and supplement of the members of the CDU 100 according to an example embodiment will be described with reference to FIGS. 12A to 12C.

As shown in FIGS. 12A and 12B, the long directions of the heat exchanger 3, the tank 5, and the pump assembly 4 extend along the X axis direction. By aligning the long directions of the members with the long direction of the CDU 100, the degree of freedom of layout in the Y axis direction, which is the short direction of the CDU 100, can be increased.

In order to increase the size of the heat exchanger 3 that greatly affects the cooling performance, in the present example embodiment, the pump assembly 4 that is long in length in the X axis direction and the heat exchanger 3 do not overlap in the X axis direction. The heat exchanger 3 can have a length increased in the X axis direction by being arranged to overlap, in the X axis, the control unit 6 having a relatively short length in the X axis direction.

The power distribution board 31 is arranged in a position not overlapping the flow path pipe in the Z axis direction. Such an arrangement can suppress damage even when liquid leakage from the flow path pipe, dropping of water droplets due to dew condensation, or the like occurs. Since the periphery of the power distribution board 31 is covered by a cover 32, it is possible to suppress liquid from being applied to the power distribution board 31 even when liquid leakage occurs.

As shown in FIGS. 12A and 12B, the tank 5 is arranged to overlap the heat exchanger 3. The length of the tank 5 in the Y axis direction is longer than that of the heat exchanger 3, and a part of the tank 5 does not overlap the heat exchanger 3. A hole portion 54 connected to the flow path pipe 22 for the secondary refrigerant discharged from the heat exchanger 3 on the lower surface of the tank 5 is arranged in a position not overlapping the heat exchanger 3 in the Z axis direction.

As shown in FIG. 12A, the tank 5 includes a reinforcement portion 55 extending in the X axis direction at the center in the Y axis direction in the tank 5. The reinforcement portion 55 is in contact with the lower surface and the upper surface of the tank 5, thereby preventing collapse even when the tank 5 is applied with a force in the up-down direction.

As shown in FIGS. 12A and 12C, no members other than the flow path pipes 23 and 24 and the cover 32 are arranged between the pump assembly 4 and the power distribution board 31 in the X axis direction. Therefore, it is easy to pull out the flow path pipes 23 and 24 connected to the inflow port and the outflow port of the pump assembly 4.

Note that the present technology can also have the following configurations.

(1)

A refrigerant circulation device including:
a primary flow path through which a primary refrigerant flows;
a secondary flow path through which a secondary refrigerant flows;
a heat exchanger connected to the primary flow path and the secondary flow path;
a housing including two first outer side surfaces extending along a first direction in plan view and two second outer side surfaces extending along a second direction intersecting the first direction, the housing accommodating the primary flow path, the secondary flow path, and the heat exchanger;
a power connector provided on the first outer side surface and protruding from the first outer side surface;
two inflow ports positioned on the first outer side surface provided with the power connector and respectively communicating with the primary flow path and the secondary flow path; and
two outflow ports positioned on the first outer side surface provided with the power connector and respectively communicating with the primary flow path and the secondary flow path; in which
at least one of the two inflow ports and at least one of the two outflow ports are arranged opposite to each other across the power connector in the first direction in the plan view.
   (2)

The refrigerant circulation device according to (1), in which
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
the secondary inflow port and the secondary outflow port are arranged opposite to each other across the power connector in the first direction.
   (3)

The refrigerant circulation device according to (1) or (2), in which
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
the primary inflow port and the primary outflow port are opposite to each other across the power connector in the first direction.
   (4)

The refrigerant circulation device according to any one of (1) to (3), in which
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
when a direction orthogonal to the first direction and the second direction is a third direction, the secondary inflow port and the secondary outflow port are on one side in the third direction relative to the power connector.
   (5)

The refrigerant circulation device according to any one of (1) to (4), in which
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
the primary inflow port and the primary outflow port are on an outside relative to the secondary inflow port and the secondary outflow port in the first direction.
   (6)

The refrigerant circulation device according to (4), in which the primary inflow port and the primary outflow port are on another side in the third direction relative to the secondary inflow port and the secondary outflow port.

(7)

The refrigerant circulation device according to any one of (1) to (6), in which
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path;
the refrigerant circulation device further includes:
a first liquid feed pipe communicating with the secondary inflow port and protruding from the first outer side surface provided with the power connector; and
a second liquid feed pipe communicating with the secondary outflow port and protruding from the first outer side surface provided with the power connector;
the secondary inflow port is on one side in the first direction relative to the power connector;
the secondary outflow port is on another side in the first direction relative to the power connector;
the first liquid feed pipe extends toward one side in the first direction; and
the second liquid feed pipe extends toward an other side in the first direction.
   (8)

A cooling device including:
the refrigerant circulation device according to (7);
a plurality of cold plates in contact with a plurality of heat sources; and
a collection manifold and a distribution manifold in communication with the plurality of cold plates; in which
the collection manifold is on one side in the first direction relative to the power connector; and
the distribution manifold is on another side in the first direction relative to the power connector.
   (9)

The cooling device according to (8), in which a protrusion amount of the power connector is larger than a protrusion amount from the first outer side surface of the primary inflow port, the secondary inflow port, the primary outflow port, or the secondary outflow port.

(10)

The cooling device according to (8) or (9), in which a width of a tip end portion of the power connector is narrower than a width of a base end portion of the power connector.

(11)

A pump assembly insertably/removably connected to a housing, the pump assembly including:
a movable portion that is positioned outside the housing in a state of being inserted into the housing and is displaceable between a first position and a second position; and
a restriction portion that restricts movement of the movable portion to the first position when the movable portion is positioned in the second position.
   (12)

The pump assembly according to (11), in which the restriction portion includes an operation portion displaceable between a third position and a fourth position, and when the operation portion moves from the third position to the fourth position, a state where movement of the movable portion to the first position is restricted is released.

(13)

The pump assembly according to (12), in which the restriction portion restricts movement of the movable portion to the first position by the operation portion moving from the fourth position to the third position along with movement of the movable portion from the first position to the second position.

(14)

The pump assembly according to (12) or (13), in which the restriction portion includes an elastic portion that biases the operation portion in a direction from the fourth position toward the third position.

(15) The pump assembly according to any one of (11) to (14), in which
the housing includes a protrusion portion protruding in a direction intersecting an insertion/removal direction of the pump assembly; and
the movable portion includes an opposing portion positioned on a deeper side in an insertion direction of the pump assembly relative to the protrusion portion and opposing the protrusion portion in the insertion/removal direction in a state where the pump assembly is inserted into the housing and the movable portion is positioned in the second position.
   (16)

The pump assembly according to (15), in which
the movable portion is displaceable between the first position and the second position by rotating about a rotation axis extending along a direction intersecting the insertion/removal direction; and
the opposing portion changes from a state of opposing the protrusion portion in the insertion/removal direction to a state of not opposing the protrusion portion in the insertion/removal direction by the movable portion moving from the second position to the first position in a state where the pump assembly is inserted into the housing.

The example embodiments disclosed here should be considered as an example in all points and not restrictive. Indeed, the above example embodiments may be embodied in a variety of forms. The above example embodiments may be omitted, replaced, or modified in various forms without departing from the scope and spirit of the appended claims.

Features of the above-described preferred example embodiments and the modifications thereof may be combined appropriately as long as no conflict arises.

While example embodiments of the present disclosure have been described above, it is to be understood that variations and modifications will be apparent to those skilled in the art without departing from the scope and spirit of the present disclosure. The scope of the present disclosure, therefore, is to be determined solely by the following claims.

What is claimed is:

1. A refrigerant circulation device comprising:
a primary flow path through which a primary refrigerant flows;
a secondary flow path through which a secondary refrigerant flows;
a heat exchanger connected to the primary flow path and the secondary flow path;
a housing including two first outer side surfaces extending along a first direction in a plan view and two second outer side surfaces extending along a second direction intersecting the first direction, the housing accommodating the primary flow path, the secondary flow path, and the heat exchanger;
a power connector provided on the first outer side surface and protruding from the first outer side surface;
two inflow ports positioned on the first outer side surface provided with the power connector and respectively communicating with the primary flow path and the secondary flow path; and
two outflow ports positioned on the first outer side surface provided with the power connector and respectively communicating with the primary flow path and the secondary flow path; wherein
at least one of the two inflow ports and at least one of the two outflow ports are opposite to each other across the power connector in the first direction in the plan view.

2. The refrigerant circulation device according to claim 1, wherein
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
the secondary inflow port and the secondary outflow port are opposite to each other across the power connector in the first direction.

3. The refrigerant circulation device according to claim 1, wherein
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
the primary inflow port and the primary outflow port are opposite to each other across the power connector in the first direction.

4. The refrigerant circulation device according to claim 1, wherein
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
assuming a direction orthogonal to the first direction and the second direction is a third direction, the secondary inflow port and the secondary outflow port are located on one side in the third direction relative to the power connector.

5. The refrigerant circulation device according to claim 1, wherein
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path; and
the primary inflow port and the primary outflow port are outward relative to the secondary inflow port and the secondary outflow port in the first direction.

6. The refrigerant circulation device according to claim 4, wherein the primary inflow port and the primary outflow port are on another side in the third direction relative to the secondary inflow port and the secondary outflow port.

7. The refrigerant circulation device according to claim 1, wherein
the two inflow ports include a primary inflow port communicating with the primary flow path and a secondary inflow port communicating with the secondary flow path;
the two outflow ports include a primary outflow port communicating with the primary flow path and a secondary outflow port communicating with the secondary flow path;
the refrigerant circulation device further includes:
a first liquid feed pipe communicating with the secondary inflow port and protruding from the first outer side surface provided with the power connector; and
a second liquid feed pipe communicating with the secondary outflow port and protruding from the first outer side surface provided with the power connector;
the secondary inflow port is on one side in the first direction relative to the power connector;
the secondary outflow port is on another side in the first direction relative to the power connector;
the first liquid feed pipe extends toward one side in the first direction; and
the second liquid feed pipe extends toward an other side in the first direction.

8. A cooling device comprising:
the refrigerant circulation device according to claim 7;
a plurality of cold plates in contact with a plurality of heat sources; and
a collection manifold and a distribution manifold in communication with the plurality of cold plates; wherein
the collection manifold is on one side in the first direction relative to the power connector; and
the distribution manifold is on another side in the first direction relative to the power connector.

9. The cooling device according to claim 8, wherein a protrusion amount of the power connector is larger than a protrusion amount from the first outer side surface of the primary inflow port, the secondary inflow port, the primary outflow port, or the secondary outflow port.

10. The cooling device according to claim 8, wherein a width of a tip end portion of the power connector is narrower than a width of a base end portion of the power connector.

11. A pump assembly insertably/removably connected to a housing, the pump assembly comprising:
a movable portion that is positioned outside the housing in a state of being inserted into the housing and is displaceable between a first position and a second position; and
a restriction portion that restricts movement of the movable portion to the first position when the movable portion is positioned in the second position.

12. The pump assembly according to claim 11, wherein the restriction portion includes an operation portion displaceable between a third position and a fourth position, and when the operation portion moves from the third position to the fourth position, a state where movement of the movable portion to the first position is restricted is released.

13. The pump assembly according to claim 12, wherein the restriction portion restricts movement of the movable portion to the first position by the operation portion moving from the fourth position to the third position along with movement of the movable portion from the first position to the second position.

14. The pump assembly according to claim 12, wherein the restriction portion includes an elastic portion to bias the operation portion in a direction from the fourth position toward the third position.

15. The pump assembly according to claim 11, wherein
the housing includes a protrusion portion protruding in a direction intersecting an insertion/removal direction of the pump assembly; and
the movable portion includes an opposing portion positioned on a deeper side in an insertion direction of the pump assembly relative to the protrusion portion and opposing the protrusion portion in the insertion/removal direction in a state where the pump assembly is inserted into the housing and the movable portion is positioned in the second position.

16. The pump assembly according to claim 15, wherein
the movable portion is displaceable between the first position and the second position by rotating about a rotation axis extending along a direction intersecting the insertion/removal direction; and
the opposing portion changes from a state of opposing the protrusion portion in the insertion/removal direction to a state of not opposing the protrusion portion in the insertion/removal direction by the movable portion moving from the second position to the first position in a state where the pump assembly is inserted into the housing.
